(19) United States
(12) Patent Application Publication
(10) Pub. No.: US 2026/0033324 A1
(43) Pub. Date: Jan. 29, 2026

(54) ENHANCED CAPACITOR FOR IMAGE SENSOR

(71) Applicant: Taiwan Semiconductor Manufacturing Company, Ltd., Hsinchu (TW)

(72) Inventors: Chieh-En Chen, Tainan City (TW); Shyh-Fann Ting, Tainan City (TW); Jen-Cheng Liu, Hsin-Chu City (TW)

(21) Appl. No.: 18/983,452

(22) Filed: Dec. 17, 2024

Related U.S. Application Data
(60) Provisional application No. 63/675,913, filed on Jul. 26, 2024.

(51) Int. Cl. H01L 23/522; H01L 23/00; H01L 25/04; H10F 39/00

(52) U.S. Cl. CPC H01L 23/5223; H01L 24/08; H01L 24/80; H01L 25/043; H10F 39/018; H10F 39/809; H10F 39/811; H01L 2224/08145; H01L 2224/80895; H01L 2224/80896

(57) ABSTRACT

Some embodiments relate to an integrated device, including: a substrate including a first doped region; an interconnect structure on the substrate and including a plurality of wire levels and via levels; a first lower contact layer extending between the substrate and the interconnect structure; a first bonding layer over the interconnect structure; a first upper contact layer extending between the interconnect structure and the first bonding layer; a capacitor in the interconnect structure, wherein the capacitor extends above an uppermost wire level of the plurality of wire levels and via levels.

### REFERENCE TO RELATED APPLICATION

This application claims the benefit of U.S. Provisional Application No. 63/675,913, filed on Jul. 26, 2024, the contents of which are incorporated by reference in their entirety.

### BACKGROUND

Integrated circuits (ICs) with image sensors are used in a wide range of modern-day electronic devices, such as, for example, cameras, cellphones, and the like. Capacitors are used to store charge within a circuit. Capacitors used within pixel circuits are subject to size restrictions based on the lateral dimensions of the pixel circuit and the height of the surrounding interconnect structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, and 1E illustrate cross-sectional views of some embodiments of a capacitor extending between a first lower contact layer at a substrate and a first upper contact layer at a first bonding layer.

FIGS. 2A, 2B, 2C, and 2D illustrate cross-sectional views of portion of an image sensor with the capacitor embodiments shown in FIGS. 1A-1D.

FIGS. 3A and 3B illustrate cross-sectional views of some embodiments of an image sensor in a two wafer stack configuration with the capacitor on the first wafer or on the second wafer, respectively.

FIGS. 4A-19B illustrate a series of cross-sectional views of some embodiments of a method of forming the capacitor of FIGS. 1A and 1B extending from a first doped region to the first upper contact layer between the first bonding layer and the interconnect structure.

FIGS. 20A-31B illustrate a series of cross-sectional views of some embodiments of a method of forming the capacitor of FIGS. 1C and 1D extending from the first lower contact layer to the first upper contact layer between the first bonding layer and the interconnect structure.

FIGS. 32-43 illustrate a series of cross-sectional views of some embodiments of a method of forming the capacitor of FIG. 1E within the first upper contact layer between the first bonding layer and the interconnect structure.

FIG. 44 illustrates a flowchart of some embodiments of a method of forming a capacitor extending between a first lower contact layer at a substrate and a first upper contact layer at a first bonding layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

An image sensor comprises a pixel array with a plurality of photodetectors and a plurality of pixel circuits coupled to the photodetectors. The plurality of pixel circuits comprise a floating diffusion node, a transfer transistor extending between the floating diffusion node and the photodetector, a reset transistor with a source/drain terminal coupled to the floating diffusion node, and an output stage coupled to the floating diffusion node. One or more capacitors are included in the pixel circuits to enhance the charge retention of the pixel circuit at different stages of reading and transferring the acquired signal to an image signal processor circuit.

In some embodiments, the image sensor spans multiple substrates bonded together through bond layers. For example, in some embodiments the reset transistor and the output stage are on a first substrate while the photodetector and the floating diffusion node are within a second substrate coupled to the first substrate by metal-to metal bonding and dielectric-to-dielectric bonding. The floating diffusion node is coupled to the output stage through a metal bond pad within the first bond layer. The one or more capacitors are formed on either the first substrate or the second substrate. In some embodiments, an application specific integrated circuit (ASIC) for interpreting the signals received from the output stage is on a third substrate coupled to a backside of the first substrate.

Some pixel circuits have capacitors confined between a lowest wire level of an interconnect structure and a highest wire level of an interconnect structure in order to electrically couple the capacitor to the pixel circuit. Reduced pixel circuit size offers higher resolution images and smaller cameras for integrated devices. Meanwhile, the bonding of multiple substrates together reduces the number of wire levels used in the interconnect structures on the first substrate and the second substrate, as the pixel circuit uses pathways extending between the first interconnect structure and the second interconnect structure to form the same paths that used to be formed in one interconnect structure. The shrinking pixel size reduces the lateral dimensions available to a pixel circuit capacitor, while the use of multiple coupled interconnect structures reduces the height available to a capacitor formed within either the first or the second interconnect structure. This reduction in both the lateral dimensions and the vertical dimensions of the available space for a back-end-of-line (BEOL) device in both of the first interconnect structure and the second interconnect structure reduces the available space within the pixel circuit for the capacitor, resulting in a lower capacitance and reduced performance as miniaturization of the technology continues. Therefore, a capacitor with increased capacitance without increasing the dimensions of the pixel circuit is desirable.

The present disclosure provides for a capacitor extending from a first lower contact layer on the substrate to a first upper contact layer at a first bonding layer of the first or second substrate. A bottom electrode of the capacitor is electrically coupled directly to a contact in the first lower contact layer or directly to a first doped region of the substrate, extending level with or past a bottom surface of the lowest wire level of the interconnect structure. Further, a top electrode of the capacitor is coupled directly to a contact in a first upper contact layer extending between the first bonding layer and the interconnect structure or directly to the first bonding layer. A top surface of the top electrode extends above the top surface of the top wire level of the interconnect structure. The increase in the height of the capacitor by extending past the upper and lower bounds of the interconnect structure increases the capacitance of the capacitor, improving the charge retention of the pixel circuit. The increase in charge retention improves the conversion gain and reduces the read noise of the image sensor, while reducing costs by omitting an unnecessary metal layer from the production process.

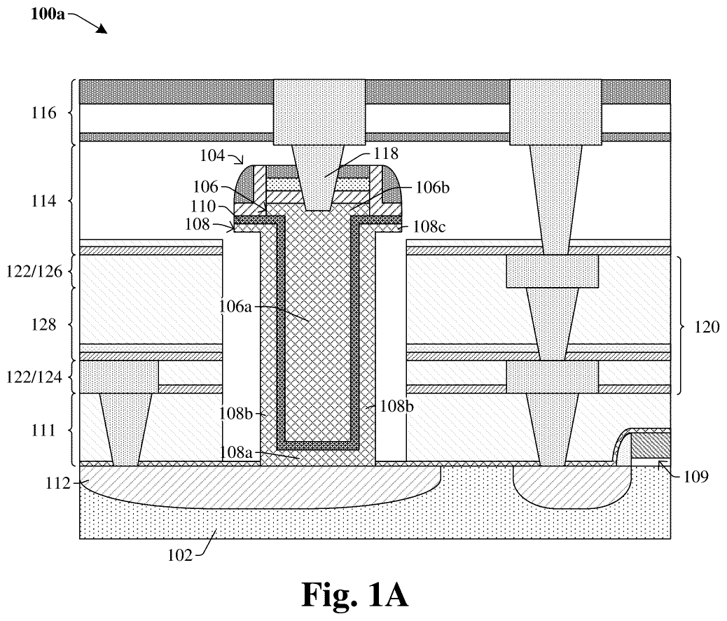

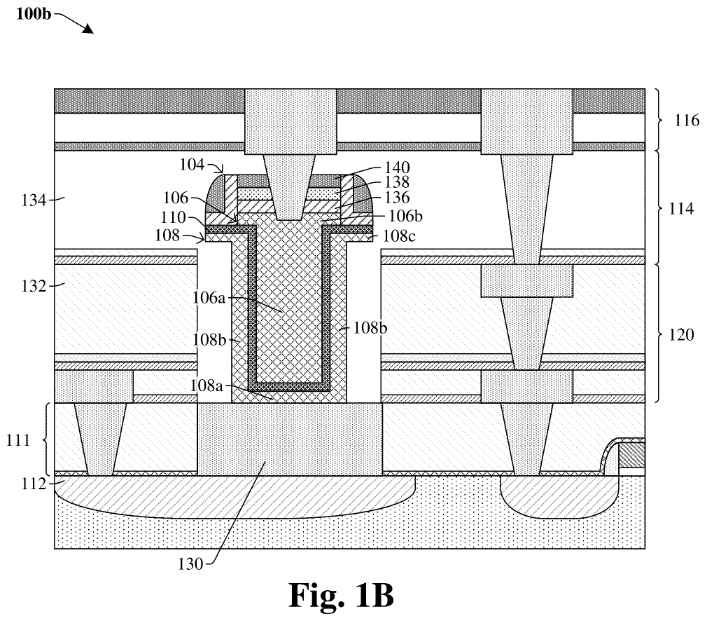

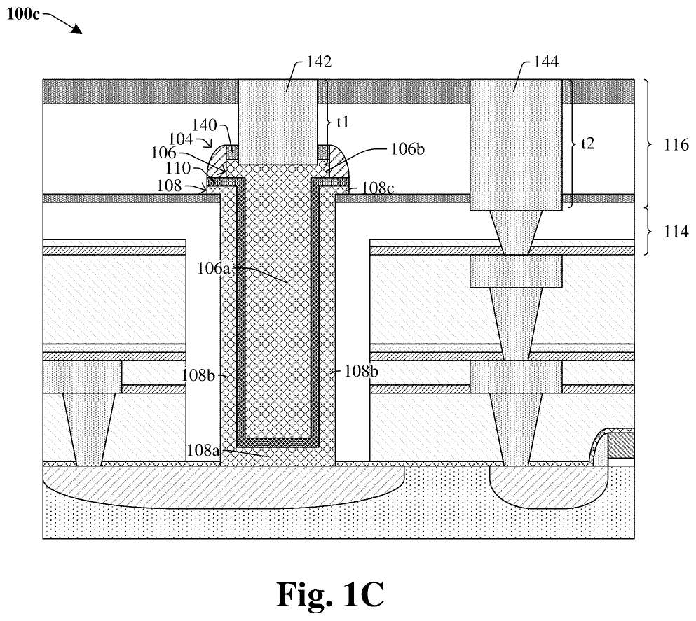

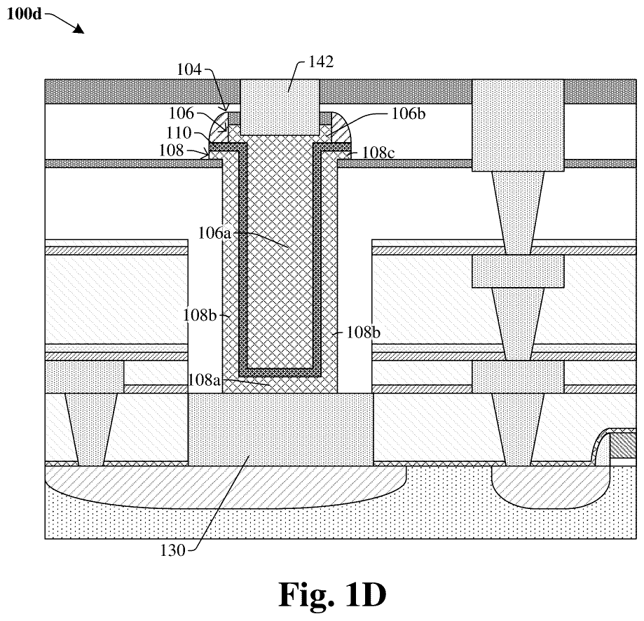

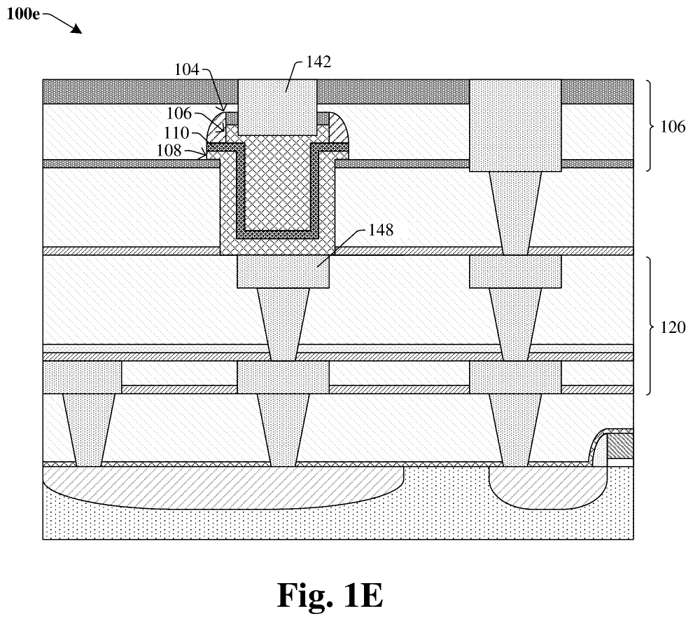

FIGS. 1A, 1B, 1C, 1D, and 1E illustrate cross-sectional views 100a, 100b, 100c, 100d, and 100e of some embodiments of a capacitor extending between a first lower contact layer at a substrate and a first upper contact layer at a first bonding layer.

As shown in the cross-sectional view 100a of FIG. 1A, a capacitor 104 is over a first substrate 102. The capacitor 104 has a top electrode 106, a bottom electrode 108, and an insulative layer 110 (e.g., high-k dielectric material or silicon dioxide) extending between the top electrode 106 and bottom electrode 108. A first plurality of semiconductor devices 109 are on the first substrate 102. In some embodiments, the first plurality of semiconductor devices 109 are or comprise a transistor device (e.g., a planar FET, a FinFET, a gate-all-around (GAA) device, etc.). The bottom electrode 108 has a base portion 108a that extends to a first lower contact layer 111 and is electrically coupled to a first doped region 112 in the first substrate 102. The bottom electrode also includes a sleeve portion 108b that extends up from the base portion 108a, and includes a collar portion 108c that extends laterally outward from an upper portion of the sleeve portion 108b. In further embodiments, the bottom electrode 108 extends to the first substrate 102 and is electrically coupled to a first doped region 112 through direct contact with the first doped region 112. In some embodiments, the top electrode 106 extends to a first upper contact layer 114 and is electrically coupled to a first bonding layer 116. In further embodiments, the top electrode 106 in includes a protrusion 106a that resides within the sleeve portion 108b of the bottom electrode, and a collar portion 106b that extends laterally outward from an upper portion of the protrusion 106a and extends upward out of the sleeve portion 108b. The top electrode 106 is electrically coupled to the first bonding layer 116 through a first upper contact 118 of the first upper contact layer 114.

A first interconnect structure 120 extends between and is coupled to the first lower contact layer 111 and the first upper contact layer 114. The first interconnect structure 120 comprises a plurality of wire levels 122 comprising a lowest wire level 124 and a highest wire level 126 of the first interconnect structure 120, and one or more via levels 128 extending between the plurality of wire levels 122. Wires of the highest wire level 126 are electrically coupled to the first bonding layer 116 through contacts of the first upper contact layer 114. Wires of the lowest wire level 124 are electrically coupled to the first plurality of semiconductor devices 109 through contacts of the first lower contact layer 111. In some embodiments, the protrusion 106a of the top electrode 106 has an uppermost portion over an upper surface of the highest wire level 126 and a lowermost portion below a bottom surface of a via level 128 immediately below the highest wire level 126.

The capacitor 104 extends beneath a bottommost surface of the lowest wire level 124 and above an uppermost surface of the highest wire level 124. In some embodiments, the bottom electrode 108 has a bottommost surface extending through the first lower contact layer 111 to the first doped region 112. This extension substantially increases the height of the capacitor 104 compared to embodiments where the top electrode 106 is coupled to a wire level of the plurality of wire levels 122 through a contact within one of the one or more via levels 128, or where the bottom electrode 108 is coupled to a wire level of the plurality of wire levels 122. As the capacitance of a capacitor is dependent upon the surface area of the electrodes, the increased height of the capacitor increases the capacitance, resulting in a greater degree of charge retention in the pixel circuit and improved conversion gain and lower read noise for the image sensor.

Further, the omission of a metal layer from between the capacitor 104 and the first bonding layer 116 may reduce the lateral footprint of the pixel circuit. For example, in embodiments with an additional metal layer formed above the interconnect structure 120 and below the first bonding layer 116, the additional metal layer is thicker than the wire levels of the interconnect structure 120. The increased thickness of the additional metal layer imposes design constraints on the how close the wires of the additional metal layer can be to each other. Removing the additional metal layer and metal layers with a similar thickness therefore reduces a size constraint on the pixel circuit, thereby increasing the flexibility of the image sensor design and reducing the lateral footprint of the individual pixel circuits.

As shown in the cross-sectional view 100b of FIG. 1B, in some embodiments, the bottom electrode 108 of the capacitor 104 extends to a first lower contact 130 of the first lower contact layer 111. In some embodiments, a lowermost surface of the bottom electrode 108 is level with the uppermost surface of the first lower contact 130 of the first lower contact layer 111 The first lower contact 130 extends past outer edges of the bottommost surface of the bottom electrode 108. A plurality of interlayer dielectric (ILD) layers 132 surround the first lower contact layer 111 and the first interconnect structure 120. A low-k layer 134 extends over the plurality of ILD layers 132 and surrounds outer sidewalls of the capacitor 104. The low-k layer 134 spaces the sidewalls of the capacitor from the plurality of ILD layers 132. The low-k layer extends from the first lower contact layer 111 to the first upper contact layer 114. In some embodiments, the plurality of ILD layers 132 are porous and trap moisture during the manufacturing process. The low-k layer 134 spaces the capacitor from the plurality of ILD layers 132 in order to mitigate any unreliability in the manufacturing of the capacitor 104 that may be caused by the trapped moisture. In some embodiments, outer sidewalls of the low-k layer 134 are directly over (e.g., aligned with) outer sidewalls of the first lower contact 130.

In some embodiments, the uppermost surface of the top electrode 106 is covered in a cap oxide layer 136, a silicon oxynitride (SiON) layer 138, and a silicon nitride (Si₃N₄) layer 140. The combination of layers covering the top electrode 106 mitigates the damage dealt to the top electrode 106 by multiple etching processes used to form openings for the first upper contact layer 114 and the first bonding layer 116.

As shown in the cross-sectional view 100c of FIG. 1C, in some embodiments, the top electrode 106 of the capacitor 104 extends to and directly contacts a first bond structure 142 of the first bonding layer 116. In some embodiments, the first bond structure 142 has a first thickness t1, and a second bond structure 144 that directly overlies and is electrically coupled to the interconnect structure 128 has a second thickness t2 that is greater than the first thickness t1. In further embodiments, the top electrode 106 is covered by the silicon nitride (Si₃N₄) layer 140, while the cap oxide layer (see 136 of FIG. 1B) and the silicon oxynitride layer (see 138 of FIG. 1C) are omitted. The reduced number of etching steps extending to the capacitor 104 results in a reduced number of insulative layers being used to cover the top electrode 106. In some embodiments, the top electrode 106 has an uppermost surface that is above a bottom surface of the first bond structure 142 of the first bonding layer 116. In other embodiments, the uppermost surface of the top electrode 106 is level with the bottom surface of the first bond structure 142 of the first bonding layer 116.

As shown in the cross-sectional view 100d of FIG. 1D, in some embodiments, the capacitor 104 both directly contacts the first bond structure 142 and the first lower contact 130. As shown in the cross-sectional view 100e of FIG. 1E, in some embodiments, the capacitor 104 is coupled between the first bond structure 142 and a wire 148 of the interconnect structure 120. In further embodiments, the wire 148 is part of the uppermost wire level of the interconnect structure 120. Coupling the capacitor between the first bond structure 142 and the wire 148 in the interconnect structure 120 results in a structure with varying capacitance based on the wire level the wire 148 is within, while maintaining the benefits of the omission of a metal layer from between the capacitor 104 and the first bonding layer 116.

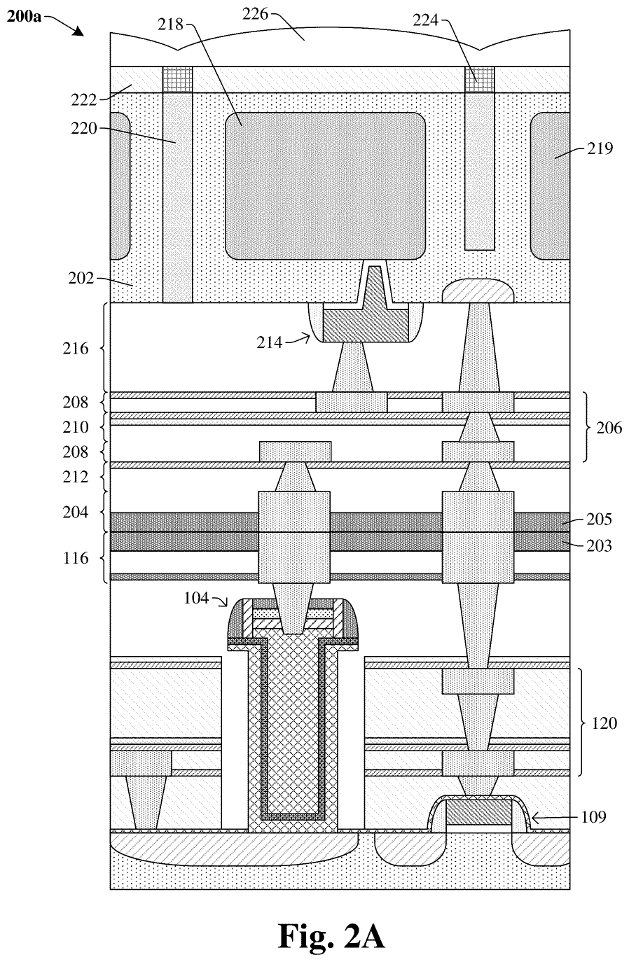

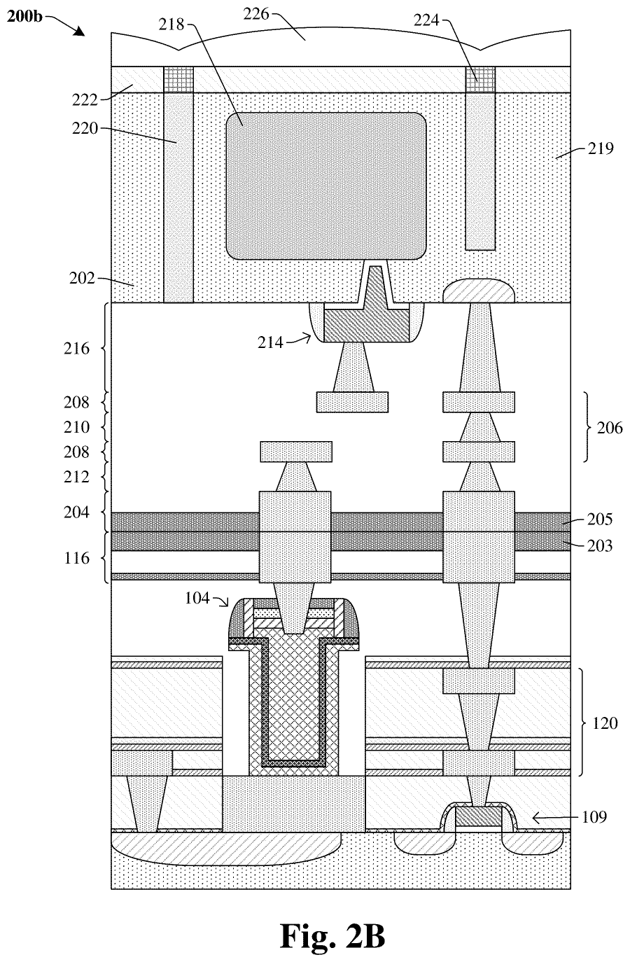

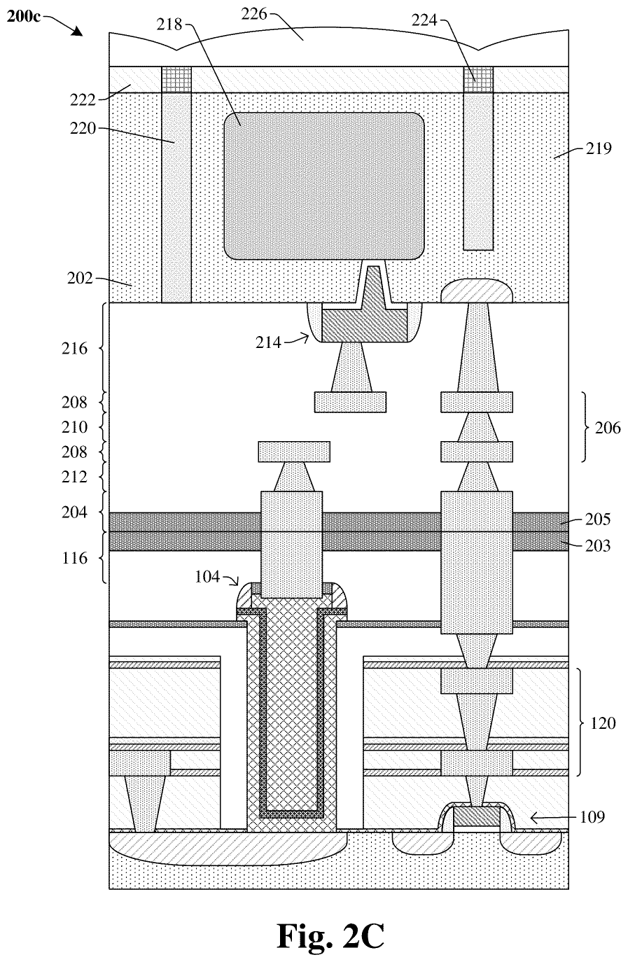

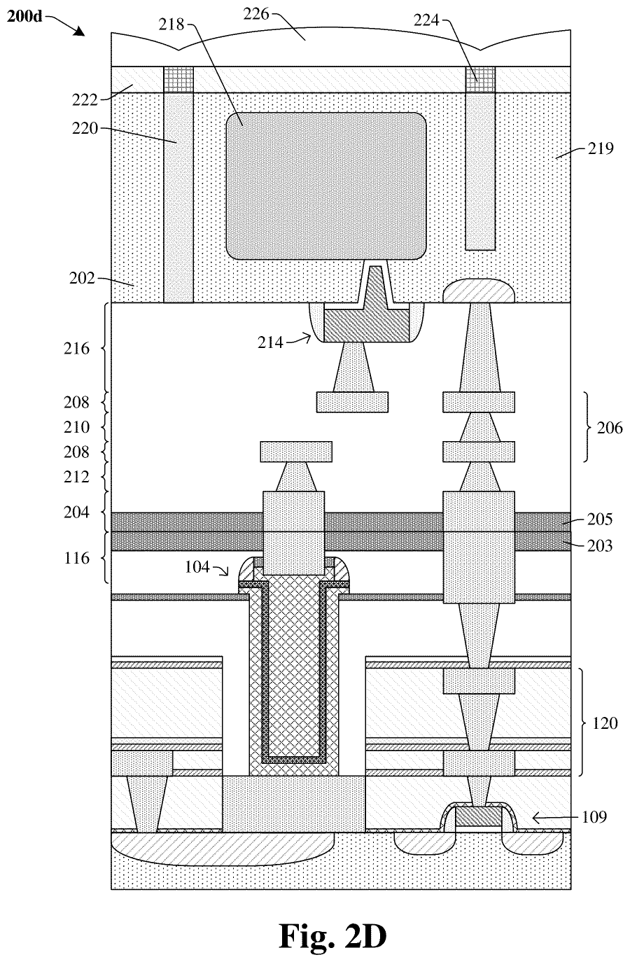

FIGS. 2A, 2B, 2C, and 2D illustrate cross-sectional views 200a, 200b, 200c, 200d of portion of an image sensor with the capacitor embodiments shown in FIGS. 1A-ID. FIGS. 2A, 2B, 2C, and 2D are described concurrently.

In some embodiments, a second substrate 202 is mechanically coupled to the first substrate 102 by a second bonding layer 204 coupled to the first bonding layer 116. The second bonding layer 204 is mechanically bonded to the first bonding layer 116 through a combination of metal-to-metal bonding and oxide-to-oxide bonding. A bonding interface layer 203 of the first bonding layer 116 is bonded to a second oxide capping layer 205 of the second bonding layer 204.

A second interconnect structure 206 extends between the second substrate 202 and the second bonding layer 204. The second interconnect structure 206 comprises a second plurality of wire levels 208 and a second plurality of via levels 210 extending between and coupling wires of the second plurality of wire levels 208. A second upper contact layer 212 couples bonding structures of the second bonding layer 204 to the second interconnect structure 206. The second interconnect structure 206 is electrically coupled to conductive paths of the first interconnect structure 120 by the first and second bonding layers 116, 204, resulting in the conductive paths extending into the second interconnect structure 206 and increasing the number of wire levels and via levels used for routing conductive paths within the circuit.

A second plurality of semiconductor devices 214 are on the second substrate 202. In some embodiments, the second plurality of semiconductor devices 214 are or comprise a transistor device (e.g., a planar FET, a FinFET, a gate-all-around (GAA) device, etc.). A second lower contact layer 216 couples the second plurality of semiconductor devices 214 to the second interconnect structure 206. In some embodiments, a photodetector 218 is in the second substrate 202, and a combination of the photodetector 218, the second plurality of semiconductor devices 214, the conductive paths, the capacitor 104, and the first plurality of semiconductor devices 109 form a pixel circuit.

In some embodiments, a deep trench isolation (DTI) structure 220 surrounds the photodetector 218. The DTI structure 220 isolates the photodetector 218 from other surrounding photodetectors 219, mitigating the amount of cross-talk and interference cause by the proximity of the different photodetectors. A plurality of color filters 222 extend over the photodetectors 218, 219. In some embodiments, the plurality of color filters 222 have different colors (e.g., red, blue, and green) that are organized in a repeating pattern across the image sensor, and are separated by a isolating grid 224 to reduce interference between the pixels.

In some embodiments, a plurality of microlenses 226 are distributed across the second substrate 202. The plurality of microlenses 226 are positioned and fabricated to direct light into the photodetectors. For example, in some embodiments, an aperture smaller than the image sensor is used to isolate the image to be recorded by the image sensor. In such an embodiment, the plurality of microlenses 226 are configured to direct the light from the aperture down into the pixels. To do this, microlenses near the outer edges of the image sensor are configured to direct light approaching the photodetectors at an narrower angle (e.g., at a first angle measured from the bottom of the second substrate 202) to instead approach the photodetector 218 at a wider angle (e.g., at a second angle measured from the bottom of the second substrate, where the second angle is greater than the first angle). The plurality of microlenses 226 may have rectangular, triangular, convex, stepped, or any other cross-sectional profile.

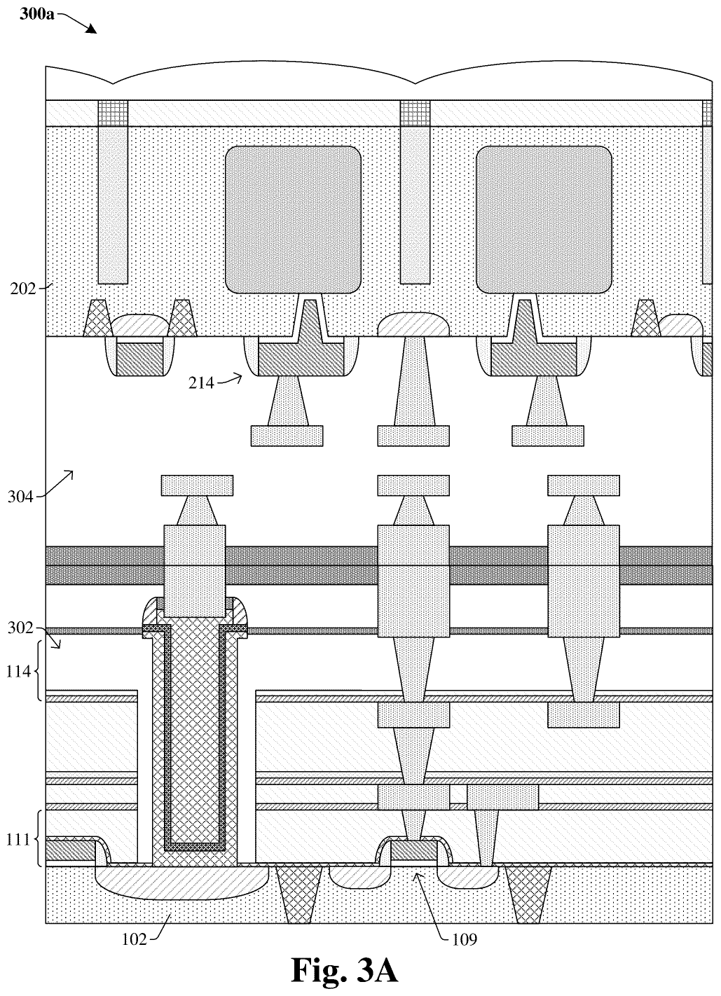

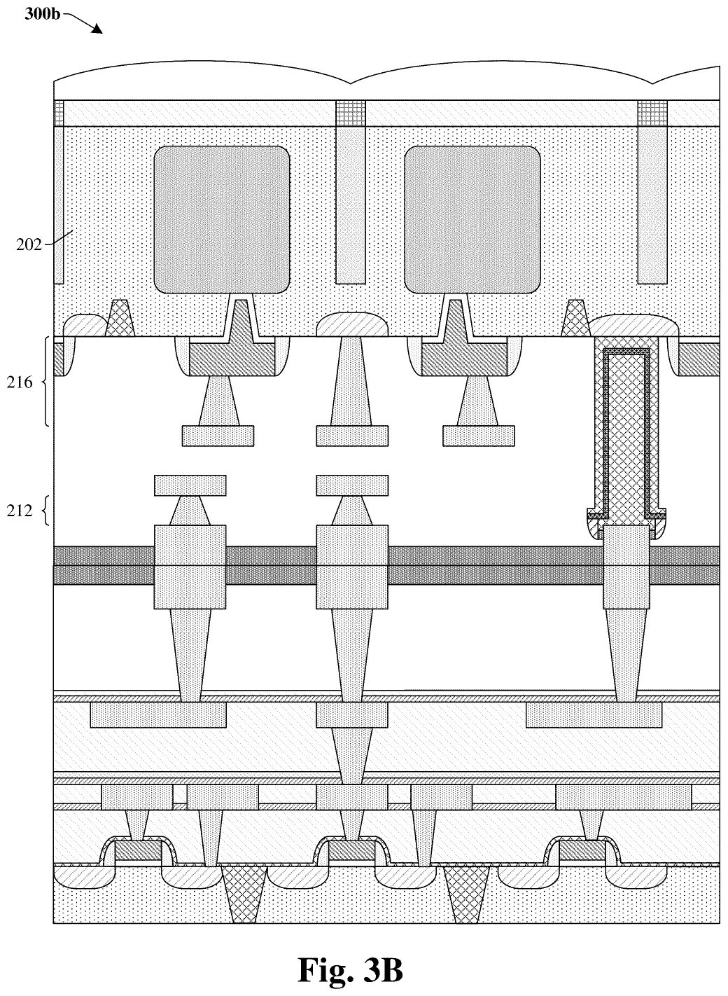

FIGS. 3A and 3B illustrate cross-sectional views 300a, 300b of some embodiments of an image sensor in a two-wafer stack configuration with the capacitor on the first wafer or on the second wafer, respectively.

As shown in the cross-sectional view 300a of FIG. 3A, in some embodiments, the capacitor 104 of FIGS. 1A-ID is used in a two-wafer stack image sensor configuration, where the first plurality of semiconductor devices 109 on the first substrate 102 form an image processing circuit (ISP) 302 and the second plurality of semiconductor devices 214 on the second substrate 202 form the pixel circuit 304. In some embodiments, a portion of the first plurality of semiconductor devices 109 on the first substrate are also part of the pixel circuit 304. In some embodiments, the capacitor 104 extends from the first upper contact layer 114 to the first lower contact layer 111 in a two-wafer stack image sensor configuration. In other embodiments, the capacitor 104 extends from the first upper contact layer 114 to the first lower contact layer 111 in a three-wafer stack image sensor configuration, where the ISP 302 is on a third substrate (not shown) and the pixel circuit 304 has components on the first substrate 102 and the second substrate 202. As shown in the cross-sectional view 300b of FIG. 3B, in some embodiments, the capacitor 104 extends between the second lower contact layer 216 and the second upper contact layer 212 on the second substrate 202 of a two-wafer stack configuration.

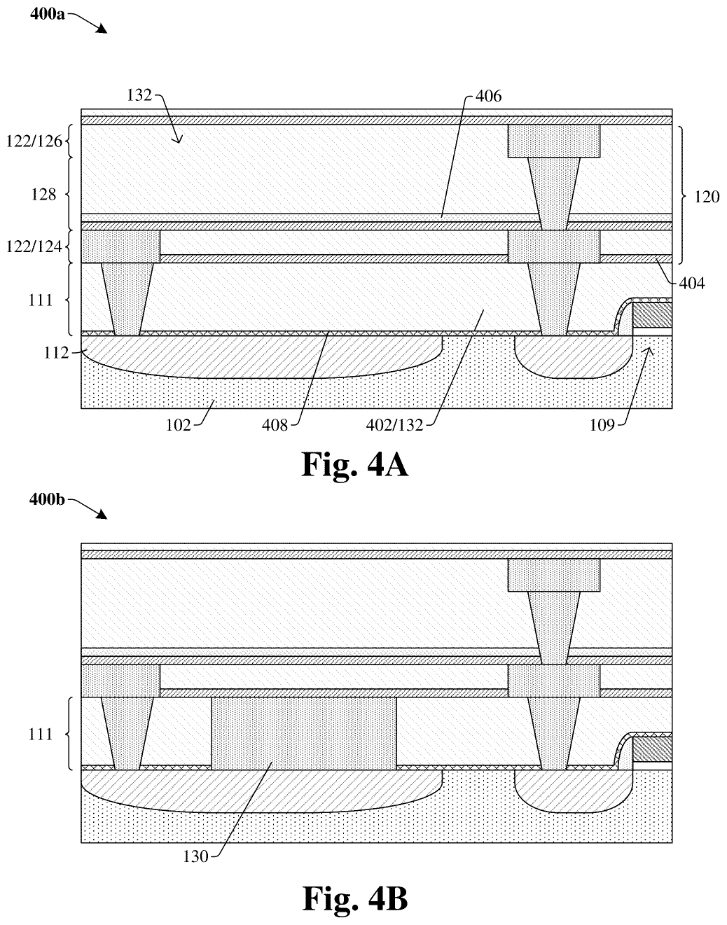

FIGS. 4A-19B illustrate a series of cross-sectional views 400a-1900b of some embodiments of a method of forming the capacitor of FIGS. 1A and 1B extending from a first doped region to the first upper contact layer between the first bonding layer and the interconnect structure. Although FIGS. 4A-19B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 400a of FIG. 4A, the first doped region 112, the first plurality of semiconductor devices 109, and the first interconnect structure 120 are formed over the first substrate 102. The first doped region 112 is comprises a greater concentration of n-type dopants or p-type dopants than the surrounding first substrate 102. In some embodiments, the first doped region is formed through one or more doping processes, implantation processes, or the like. In some embodiments, the first plurality of semiconductor devices 109 are formed by one or more implantation processes (to form source/drain regions within the first substrate 102), a plurality of deposition processes (to form gate dielectrics, gate terminals, and spacers on the first substrate 102), and a plurality of etching processes (to pattern the gate dielectrics, gate terminals, and spacers). In some embodiments, one or more masking layers are formed using photolithography to preserve portions of the first substrate 102 and the gate terminals during the implantation and patterning processes.

In some embodiments, the first interconnect structure 120 and the first lower contact layer are formed using one or more damascene processes. That is, an ILD layer 402 of the plurality of ILD layers 132 is formed over the first substrate 102. A plurality of openings are formed in the ILD layer 402 by patterning a masking layer and etching the ILD layer 402 based on the pattern of the masking layer. The masking layer is then removed before a metal layer is deposited, filling the plurality of openings. A planarization process (e.g., a chemical mechanical planarization (CMP) process) is then used to remove portions of the metal layer over the ILD layer 402. An etch stop layer 404 is formed over the ILD layer 402, and the process is repeated one or more times to form the first interconnect structure 120. In some embodiments, a dual damascene process is used to form one or more wire levels and via levels of the first interconnect structure 120. In further embodiments, a second insulative layer 406 is formed over the etch stop layer 404 before a dual damascene process is performed to better protect the underlying wire level.

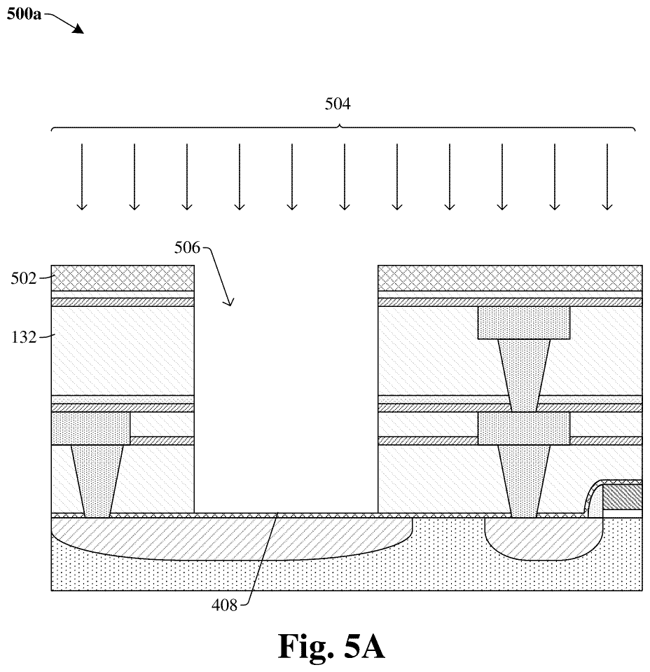

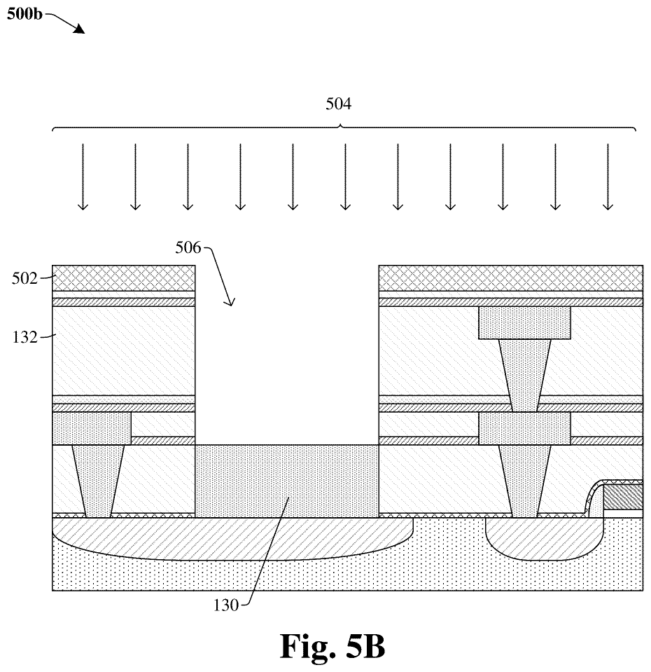

In some embodiments, the gate terminals of the first plurality of semiconductor devices 109, the contacts of the first lower contact layer 111, the plurality of wire levels 122, and the plurality of via levels 128 are or comprise a conductive material, such as copper, nickel, aluminum, tungsten, titanium, titanium nitride, a metal alloy, a combination of the foregoing, or the like. In some embodiments, the ILD layers 132 are or comprise an insulative material such as silicon oxide (SiO₂) or the like. In some embodiments, the etch stop layers 404 are or comprise an insulative material such as silicon carbide (SiC) or the like. In some embodiments, the second insulative layers 406 are or comprise tetraethyl orthosilicate (TEOS) or the like. In some embodiments, a contact etch stop layer (CESL) 408 is formed on the first substrate 102 before the plurality of ILD layers 132 are formed. As shown in the cross-sectional view 400b of FIG. 4B, in some embodiments, the first lower contact 130 is formed concurrently with forming other contacts of the first lower contact layer 111. The first figure of each figure number (e.g., the figures denoted with “A” of FIGS. 5A-19A) continue from the embodiments represented by FIG. 4A, with the first lower contact 130 omitted. Figs. The second figure of each figure number (e.g., the figures denoted with “B” of FIGS. 5B-19B) continue from the embodiments represented by FIG. 4B, with the capacitor (see 104 of FIG. 1B) coupled to the first lower contact 130.

As shown in the cross-sectional views 500a, 500b of FIG. 5A and FIG. 5B, a first masking layer 502 is formed over the plurality of ILD layers 132. In some embodiments, the first masking layer 502 is or comprises a photoresist and is patterned using photolithography. The first masking layer 502 is patterned to have an opening corresponding to the extension of the low-k layer (see 134 of FIG. 1B) through the plurality of ILD layers 132.

As shown in FIG. 5A, after the first masking layer 502 is formed, a first etching process 504 is performed, etching through the plurality of ILD layers 132 to the CESL 408. As shown in FIG. 5B, the first etching process 504 etches through the plurality of ILD layers 132 to the first lower contact 130. In some embodiments, the first etching process 504 is or comprises a dry etch or the like. The first etching process 504 results in a first opening 506 extending through the plurality of ILD layers 132. The first opening 506 corresponds to the opening in the first masking layer 502. The first masking layer 502 is subsequently removed.

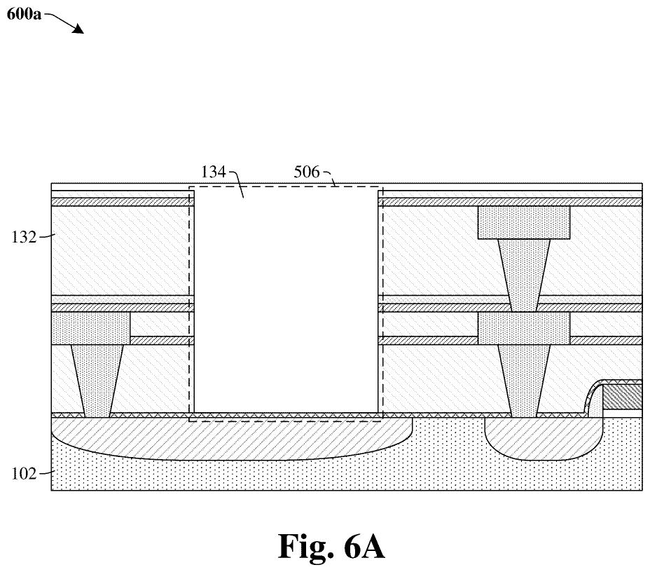

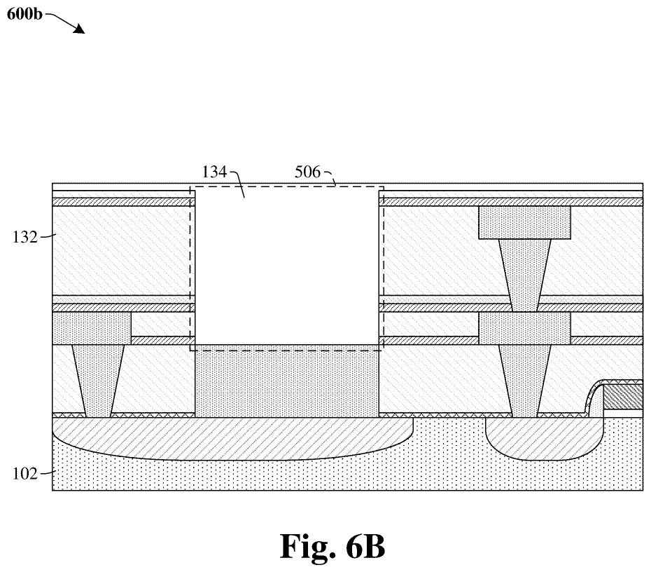

As shown in the cross-sectional views 600a, 600b of FIGS. 6A and 6B, the low-k layer 134 is formed over the first substrate 102. The low-k layer 134 fills the first opening 506 and extends over upper surfaces of the plurality of ILD layers 132. In some embodiments, the low-k layer 134 is or comprises a low-k insulative material (e.g., a material with a small dielectric constant relative to silicon dioxide (SiO₂)), such as porous silicon dioxide (SiO₂), organosilicate glass (OSG), or the like. In some embodiments, the low-k layer 134 is formed using one or more of a physical vapor deposition (PVD), atomic layer deposition (ALD), chemical vapor deposition (CVD), or the like. In some embodiments, after the low-k layer 134 is formed, a planarization process (e.g., a CMP process) is used to remove portions of the low-k layer 134, resulting in the low-k layer 134 having a substantially flat upper surface.

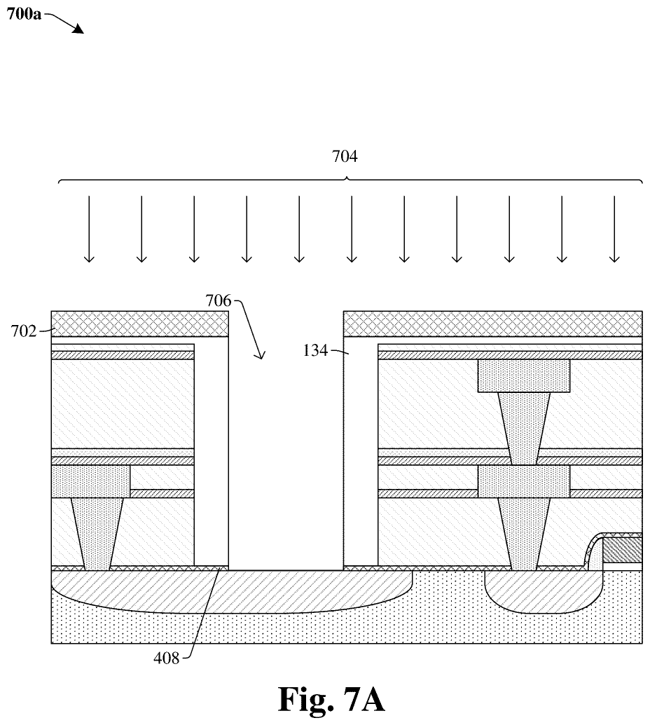

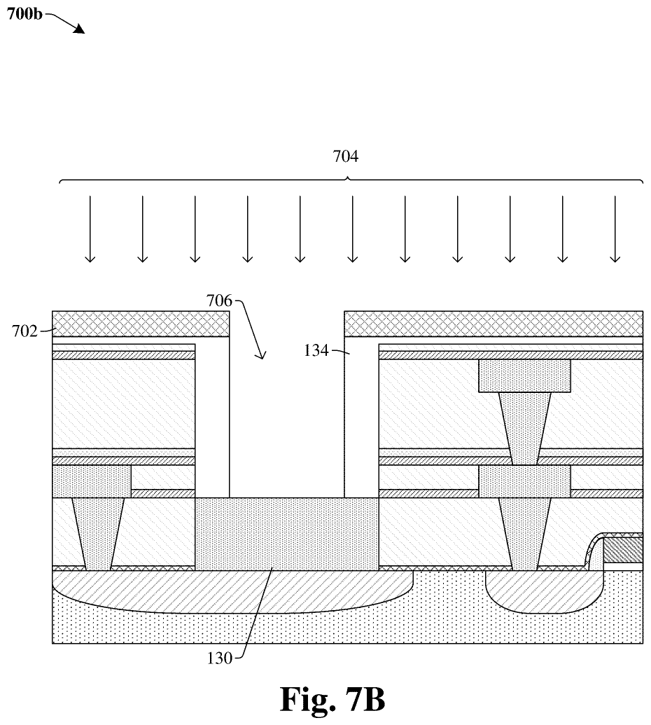

As shown in the cross-sectional views 700a, 700b of FIGS. 7A and 7B, a second masking layer 702 is formed over the plurality of ILD layers 132. In some embodiments, the second masking layer 702 is or comprises a photoresist and is patterned using photolithography. The second masking layer 702 is patterned to have an opening corresponding to the extension of the capacitor (see 104 of FIG. 1A) through the low-k layer 134.

As shown in FIG. 7A, after the second masking layer 702 is formed, a second etching process 704 is performed, etching through the low-k layer 134 and the CESL 408. As shown in FIG. 7B, the second etching process 704 etches to the first lower contact 130. In some embodiments, the second etching process 704 is or comprises a dry etch or the like. The second etching process 704 results in a second opening 706 extending through the low-k layer 134 and the CESL 408. The second opening 706 corresponds to the opening in the second masking layer 702. The second masking layer 702 is subsequently removed.

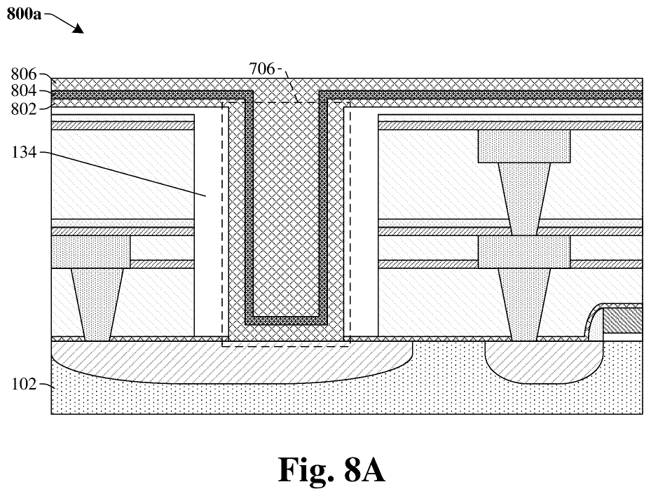

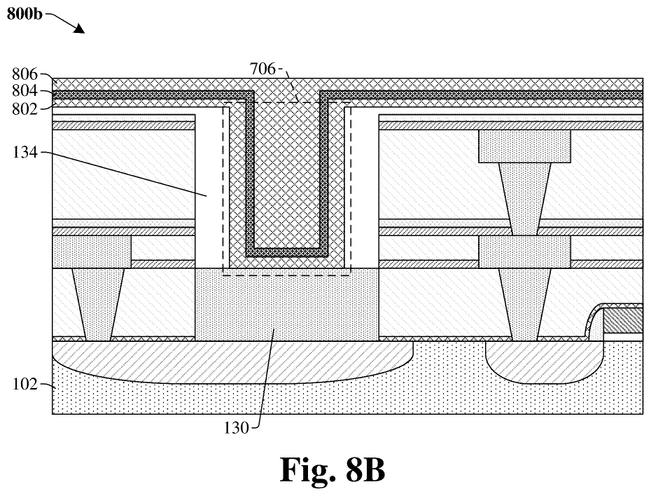

As shown in the cross-sectional views 800a, 800b of FIGS. 8A and 8B, a first conformal metal layer 802, a first conformal high-k insulative layer 804, and a second conformal metal layer 806 are formed over the first substrate 102. The first conformal metal layer 802, the first conformal high-k insulative layer 804, and the second conformal metal layer 806 combined fill the second opening 706 and extend over the upper surface of the low-k layer 134. In some embodiments, the first conformal metal layer 802 and the second conformal metal layer 806 are or comprise a conductive metal, such as titanium (Ti), titanium nitride (TiN), copper (Cu), nickel (Ni), aluminum (Al), tungsten (W), tantalum (Ta), tantalum nitride (TaN), a metal alloy, a combination of the foregoing, or the like. In some embodiments, the first conformal high-k insulative layer 804 is or comprises a high-k insulative material (e.g., an insulative material with a high dielectric constant relative to silicon dioxide (SiO₂)), such as hafnium oxide (HfO₂), hafnium silicate (HfSiO₄), zirconium dioxide (ZrO₂), zirconium silicate (ZrSiO₄), Aluminum oxide (Al₂O₃), or the like. In some embodiments, the first conformal metal layer 802, the first conformal high-k insulative layer 804, and the second conformal metal layer 806 are formed using one or more of PVD, ALD, CVD, or the like. As shown in FIG. 8A, the first conformal metal layer 802 extends to the first substrate 102. As shown in FIG. 8B, the first conformal metal layer 802 extends to the first lower contact 130.

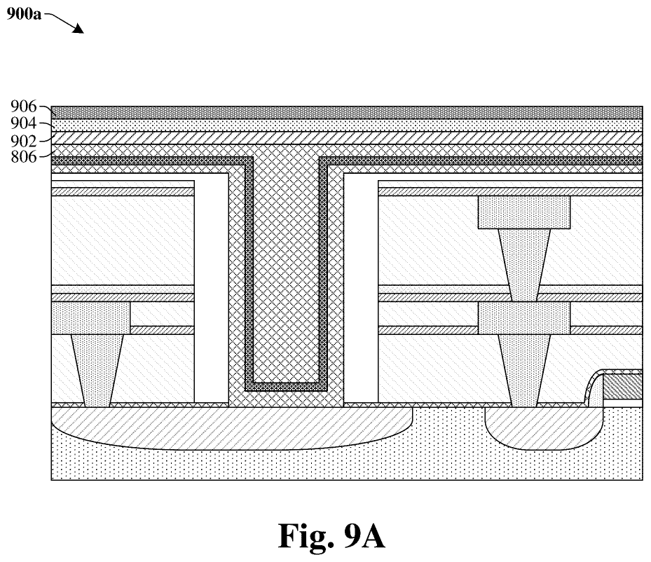

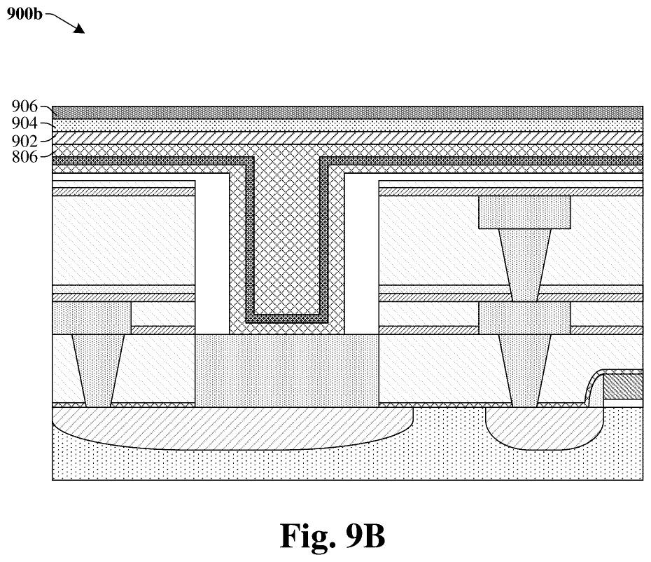

As shown in the cross-sectional views 900a, 900b of FIGS. 9A and 9B, a first conformal cap oxide layer 902, a conformal silicon oxynitride (SiON) layer 904, and a first conformal silicon nitride (Si₃N₄) layer 906 are formed over the second conformal metal layer 806. The first conformal cap oxide layer 902 is or comprises an oxide, such a silicon oxide (SiO₂) or the like. In some embodiments, the first conformal cap oxide layer 902, the conformal silicon oxynitride (SiON) layer 904, and the first conformal silicon nitride (Si₃N₄) layer 906 are formed using one or more of PVD, ALD, CVD, or the like.

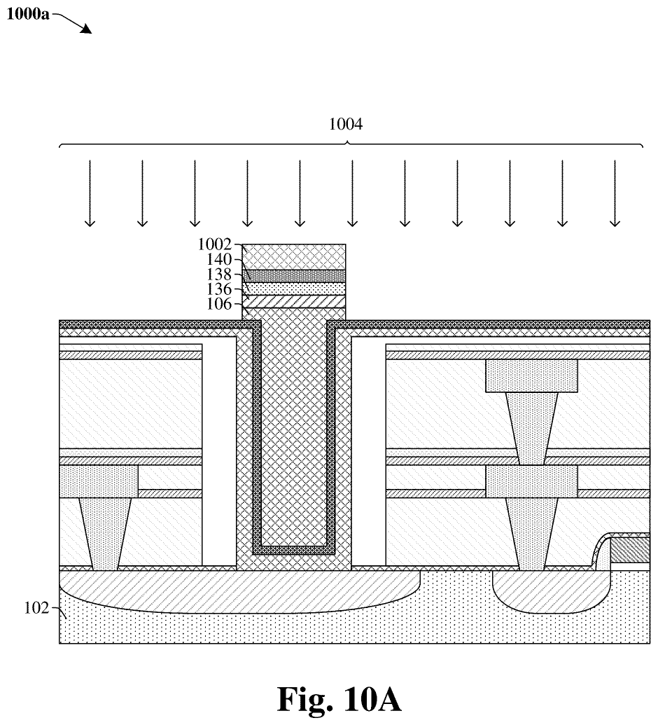

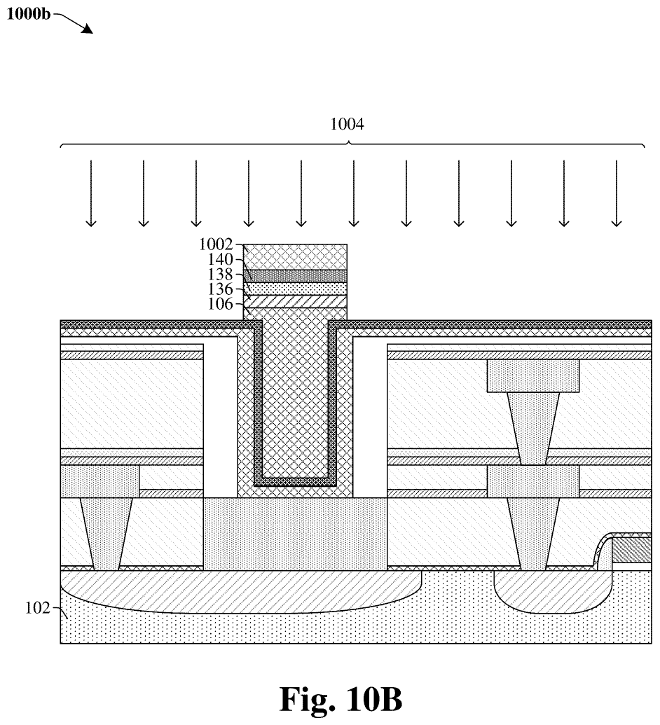

As shown in the cross-sectional views 1000a, 1000b of FIGS. 10A and 10B, in some embodiments, a third masking layer 1002 is formed over the first conformal silicon nitride (Si₃N₄) layer (see 906 of FIG. 9). The third masking layer 1002 is patterned using capacitor top metal (CTM) mask lithography and has a pattern corresponding to the lateral dimension of the top electrode 106. Further, a third etch 1004 is performed on the substrate, removing portions of the second conformal metal layer (see 806 of FIG. 8), the first conformal cap oxide layer (see 902 of FIG. 9), the conformal silicon oxynitride (SiON) layer (see 904 of FIG. 9), and the first conformal silicon nitride (Si₃N₄) layer (see 906 of FIG. 9). After the third etch 1004, the top electrode 106, the cap oxide layer 136, the silicon oxynitride (SiON) layer 138, and the silicon nitride (Si₃N₄) layer 140 remain on the first substrate 102. In embodiments including the third masking layer 1002, the third masking layer 1002 is subsequently removed.

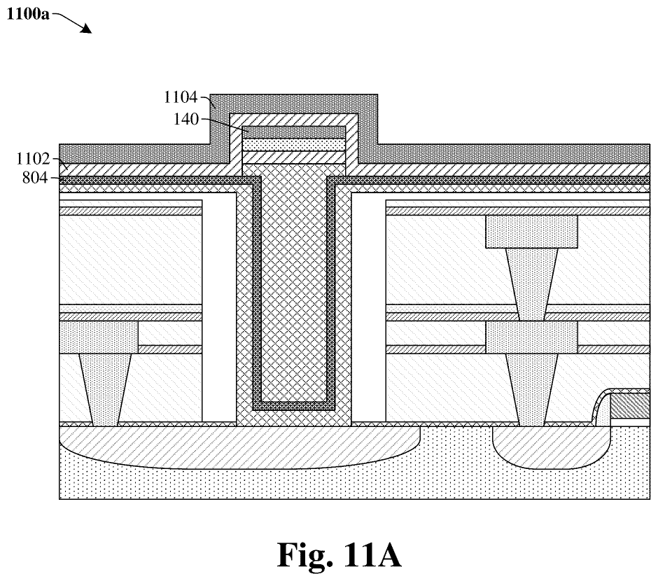

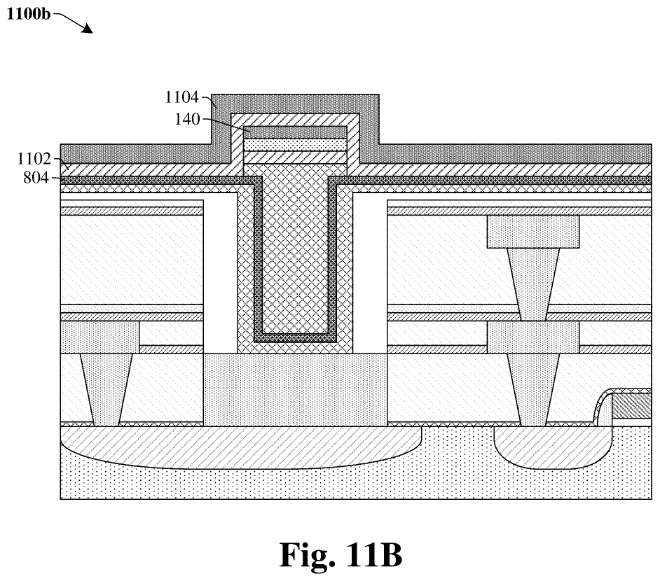

As shown in the cross-sectional views 1100a, 1100b of FIGS. 11A and 11B, a second conformal cap oxide layer 1102 and a second conformal silicon nitride (Si₃N₄) layer 1104 are formed over the silicon nitride (Si₃N₄) layer 140 and exposed surfaces of the first conformal high-k insulative layer 804. In some embodiments, the second conformal cap oxide layer 1102 comprises a same material as the cap oxide layer 136. In some embodiments, the second conformal cap oxide layer 1102 and the second conformal silicon nitride (Si₃N₄) layer 1104 are formed using one or more of PVD, ALD, CVD, or the like.

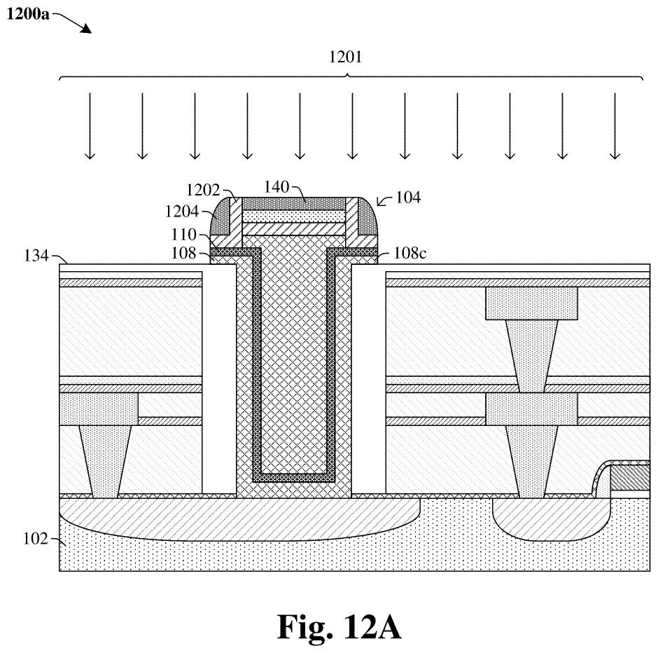

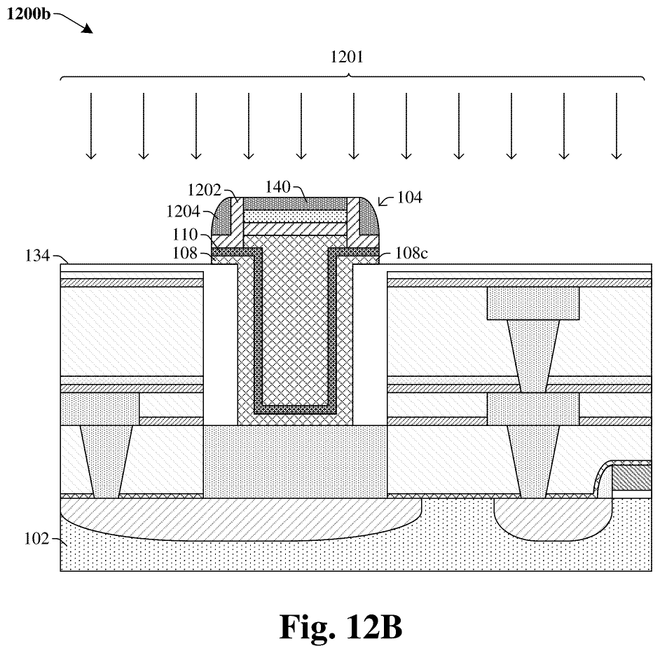

As shown in the cross-sectional views 1200a, 1200b of FIGS. 12A and 12B, a blanket etch 1201 is performed over the first substrate 102. The blanket etch 1201 removes portions of the second conformal cap oxide layer (see 1102 of FIG. 11), the second conformal silicon nitride (Si₃N₄) layer (see 1104 of FIG. 11), the first conformal high-k insulative layer (see 804 of FIG. 8), and the first conformal metal layer (see 802 of FIG. 8). After the blanket etch 1201, the bottom electrode 108, the insulative layer 110, an oxide spacer 1202, and a silicon nitride (Si₃N₄) spacer 1204 remain on the first substrate 102, and the low-k layer 134 is exposed. In some embodiments, the low-k layer 134 is partially etched, resulting in the low-k layer 134 having an upper surface that is recessed beneath the collar portion 108c of the bottom electrode 108. The capacitor 104 remains on the first substrate 102.

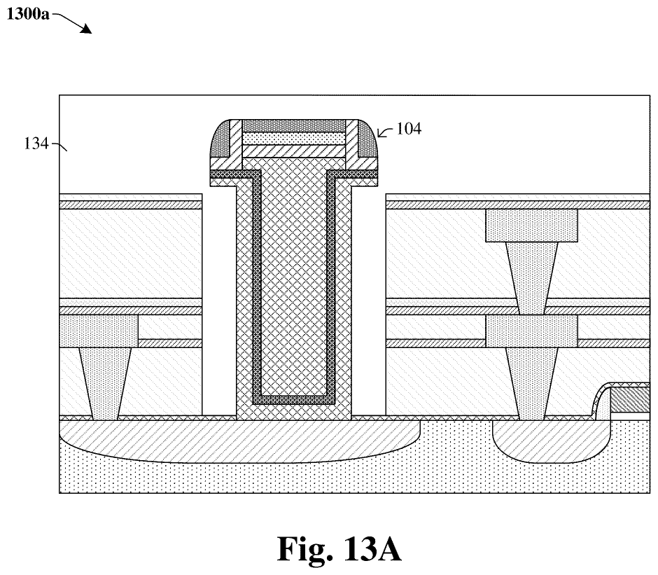

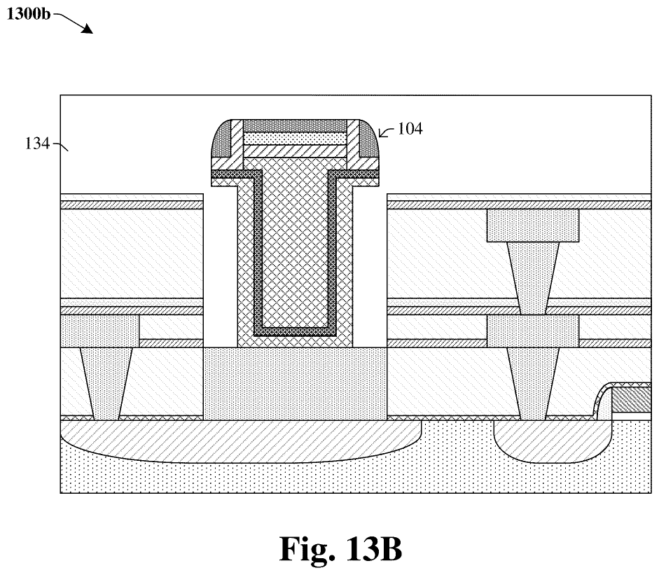

As shown in the cross-sectional views 1300a, 1300b of FIGS. 13A and 13B, additional low-k material is deposited over the capacitor 104, extending the low-k layer 134 over the capacitor 104. The additional low-k material is formed using one or more of PVD, ALD, CVD, or the like. In some embodiments, a planarization process (e.g., a CMP process) is performed after depositing the additional low-k material, removing portions of the low-k layer 134 and forming a substantially flat upper surface.

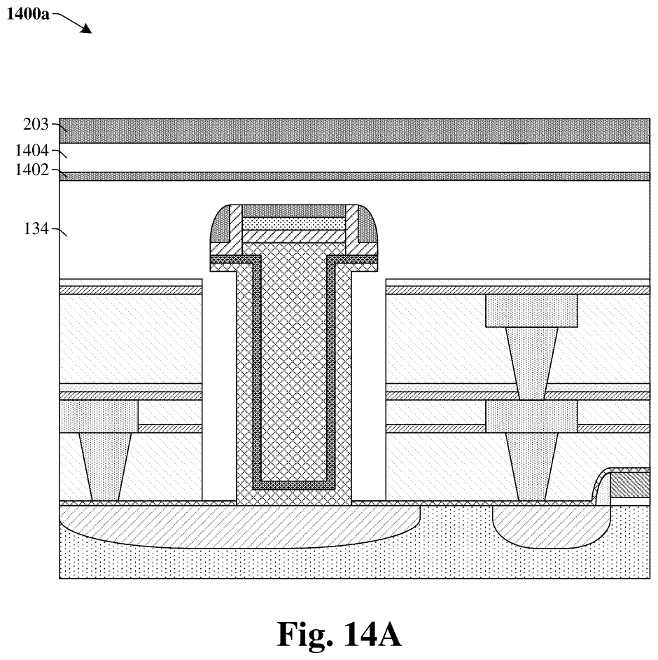

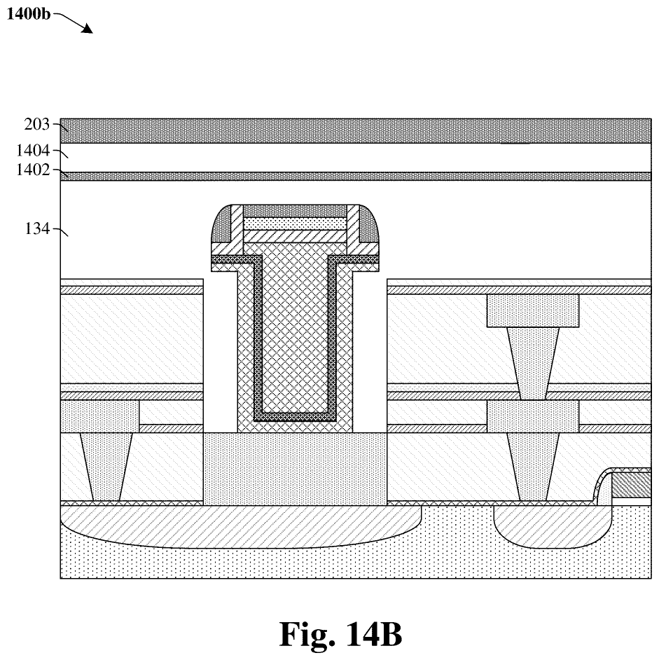

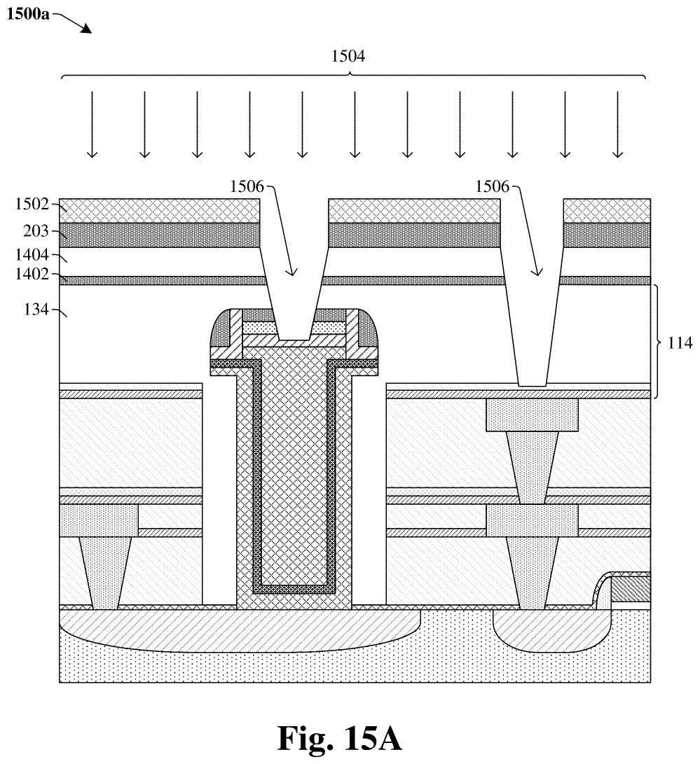

As shown in the cross-sectional views 1400a, 1400b of FIGS. 14A and 14B, a second etch stop layer 1402, an oxide fill layer 1404, and a bonding interface layer 203 are deposited over the low-k layer 134. In some embodiments, the second etch stop layer 1402 is or comprises an insulative material other than silicon dioxide (SiO₂), such as silicon nitride (Si₃N₄) silicon oxynitride (SiON), or the like. In some embodiments, the oxide fill layer 1404 is or comprises silicon dioxide (SiO₂), a low-k oxide material, or the like. In some embodiments, the bonding interface layer 203 is or comprises an insulative material such as silicon oxynitride (SiON), or the like. In some embodiments, the second etch stop layer 1402, the oxide fill layer 1404, and the bonding interface layer 203 are formed using one or more of PVD, ALD, CVD, or the like.

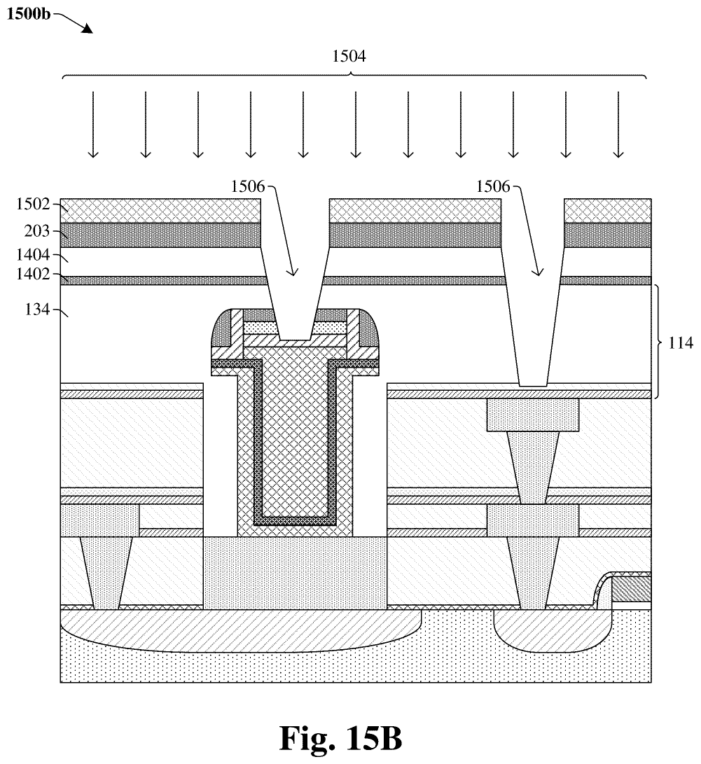

As shown in the cross-sectional views 1500a, 1500b of FIGS. 15A and 15B, a fourth masking layer 1502 is formed over the bonding interface layer 203. In some embodiments, the fourth masking layer 1502 is or comprises a photoresist and is patterned using photolithography. The fourth masking layer 1502 is patterned to have openings corresponding to contacts of the first upper contact layer (see 114 of FIG. 1A).

After the fourth masking layer 1502 is formed, a fourth etching process 1504 is performed, etching through the bonding interface layer 203, the oxide fill layer 1404, the second etch stop layer 1402, and the low-k layer 134. In some embodiments, the fourth etching process 1504 is or comprises a dry etch or the like. The fourth etching process 1504 results in third openings 1506. The third openings 1506 correspond to the openings in the fourth masking layer 1502 and the positions of the contacts of the first upper contact layer (see 114 of FIG. 1A). The fourth masking layer 1502 is subsequently removed.

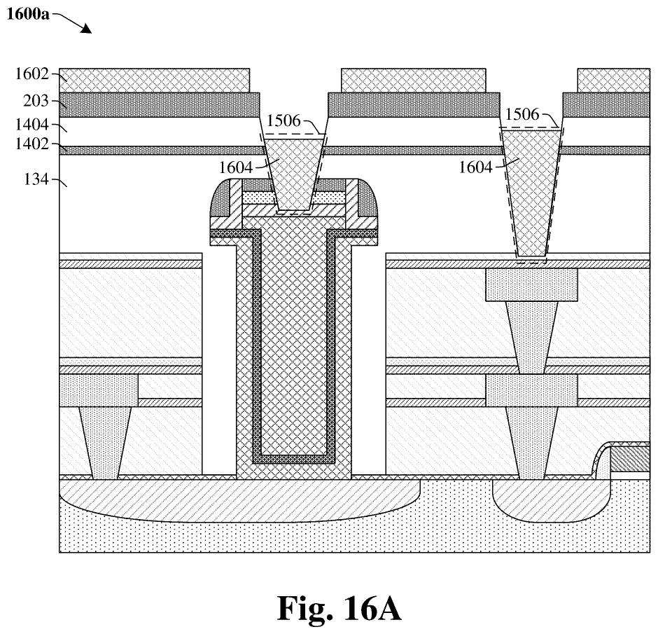

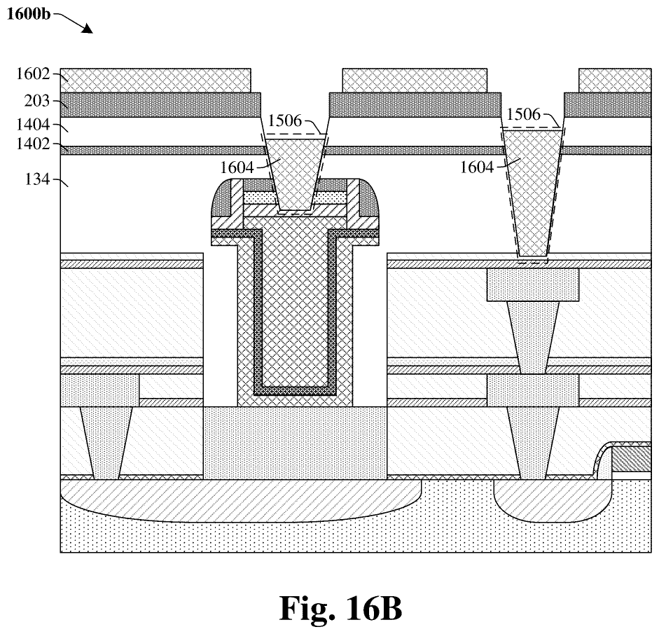

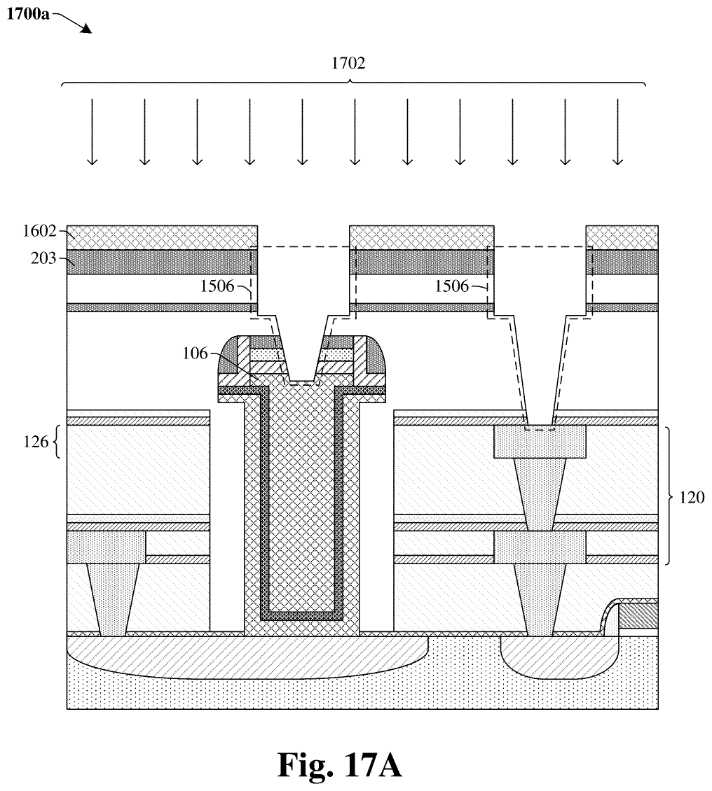

As shown in the cross-sectional views 1600a, 1600b of FIGS. 16A and 16B, a fifth masking layer 1602 is formed over the bonding interface layer 203 and in the third openings 1506. In some embodiments, the fifth masking layer 1602 is or comprises a photoresist and is patterned using photolithography. The fifth masking layer 1602 is patterned to have openings corresponding to bond structures of the first bonding layer (see 116 of FIG. 1A). In some embodiments, portions of the fifth masking layer 1602 form insulative plugs 1604 that reduce the amount of material that is removed in lower portions of the third openings 1506 in the subsequent etching process.

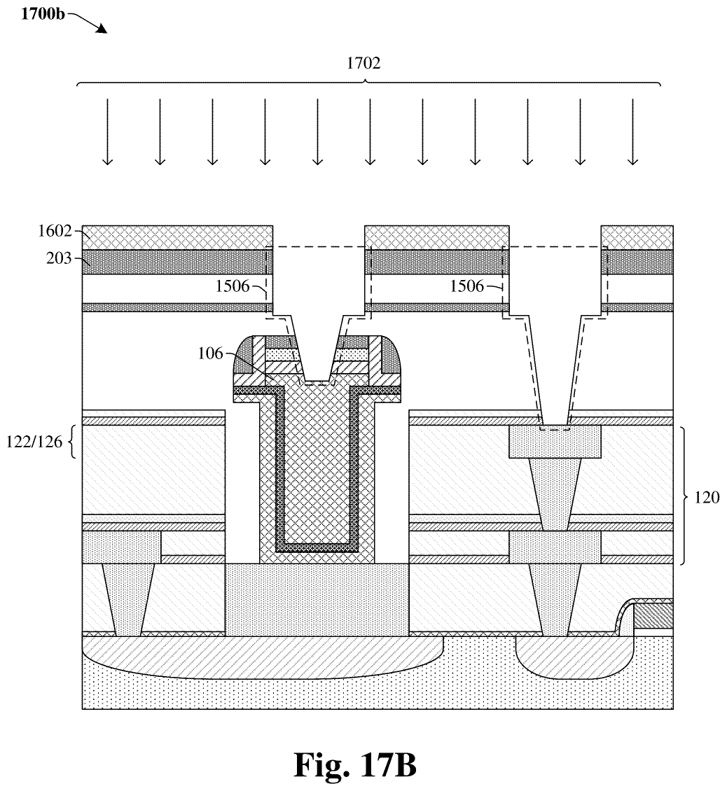

As shown in the cross-sectional views 1700a, 1700b of FIGS. 17A and 17B, after the fifth masking layer 1602 is formed, a fifth etching process 1702 is performed, the fifth etching process 1702 expands the third openings 1506, removing portions of the bonding interface layer 203 and the insulative plugs 1604. In some embodiments, the fifth etching process 1702 is or comprises a dry etch or the like. After the fifth etching process, the third opening 1506 corresponding to the position of the first upper contact (see 118 of FIG. 1A) extends to the top electrode 106 and the third openings 1506 corresponding to the position of other contacts in the first upper contact layer (see 114 of FIG. 1A) extend to the uppermost wire level 126 of the first interconnect structure 120. Further, upper portions of the third openings corresponding to the bond structures of the first bonding layer (see 116 of FIG. 1C) are etched. The fifth masking layer 1602 is subsequently removed.

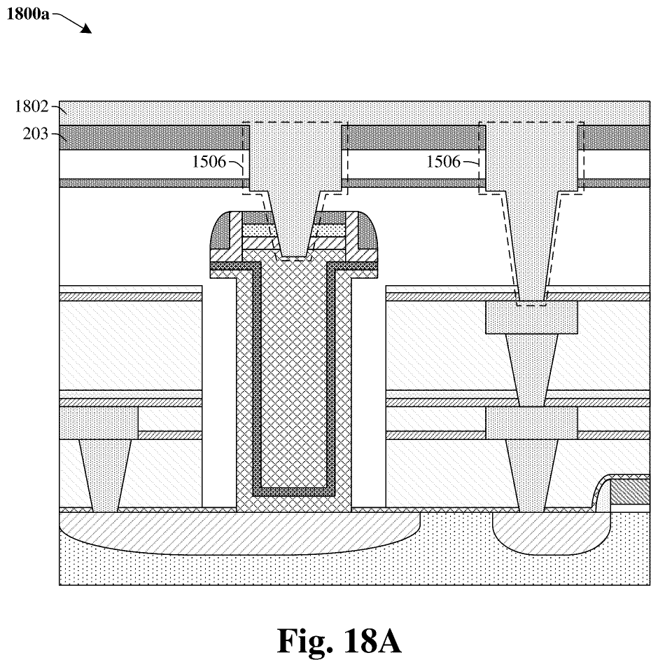

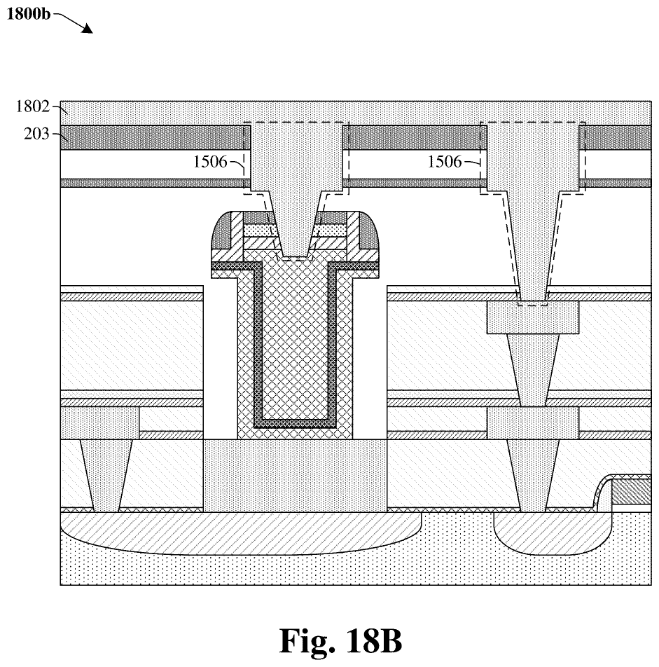

As shown in the cross-sectional views 1800a, 1800b of FIGS. 18A and 18B, a third conformal metal layer 1802 is formed over the bonding interface layer 203. The third conformal metal layer is or comprises a conductive material, such as copper, nickel, aluminum, tungsten, titanium, titanium nitride, a metal alloy, a combination of the foregoing, or the like. The third conformal metal layer 1802 extends into the third openings 1506 and over the upper surface of the bonding interface layer 203. In some embodiments, the third conformal metal layer 1802 is formed using one or more of PVD, ALD, CVD, or the like.

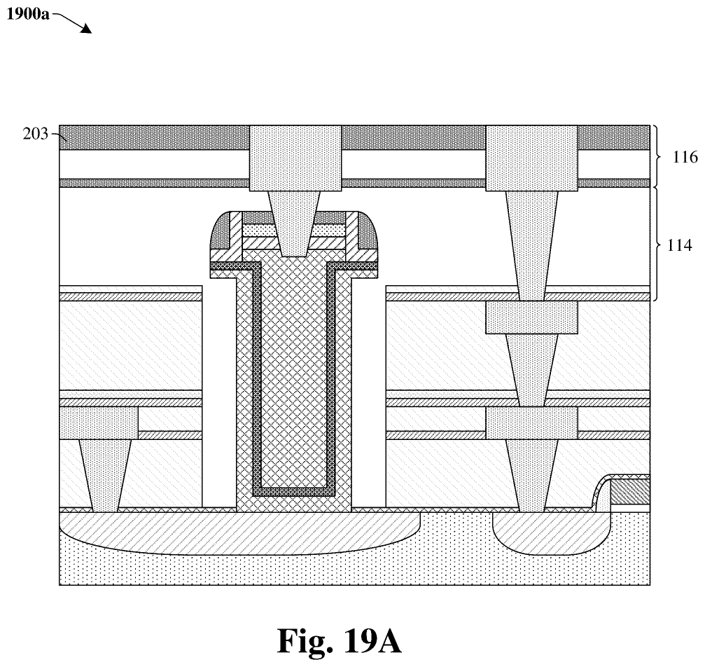

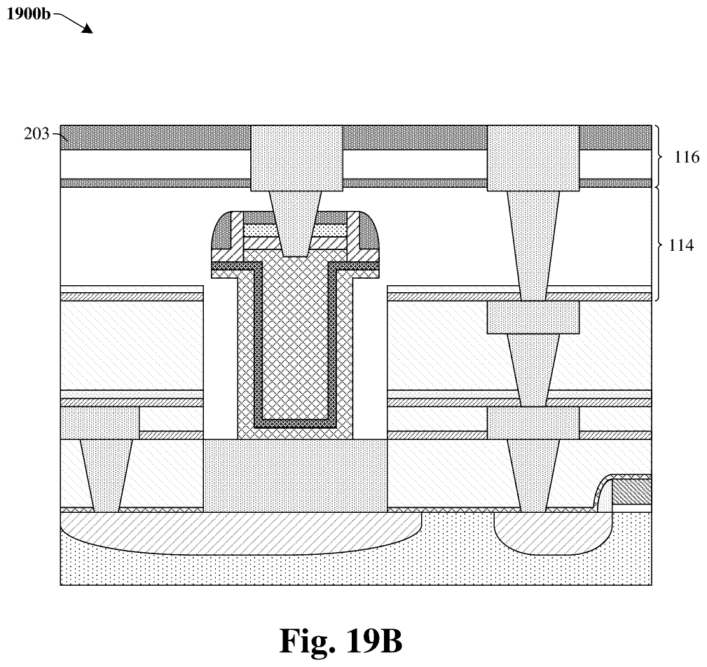

As shown in the cross-sectional views 1900a, 1900b of FIGS. 19A and 19B, a planarization process (e.g., a CMP process) is performed. The planarization process removes portions of the third conformal metal layer (see 1802 of FIG. 18) above the bonding interface layer 203. After the planarization process, the bond structures of the first bonding layer 116 and the contacts of the first upper contact layer 114 remain on first substrate 102.

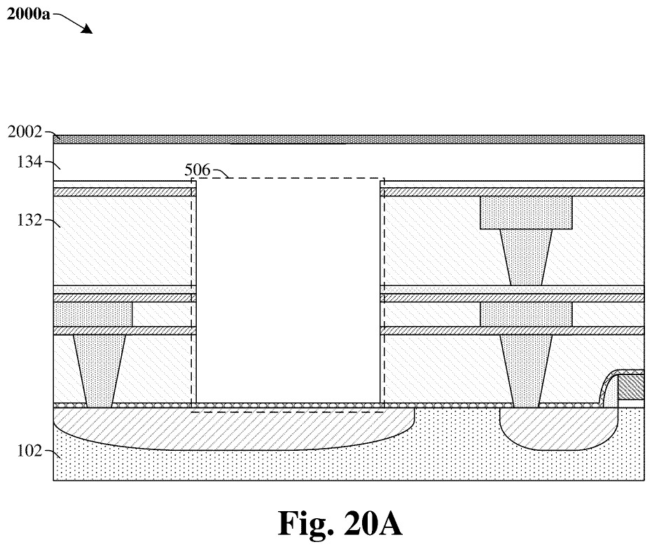

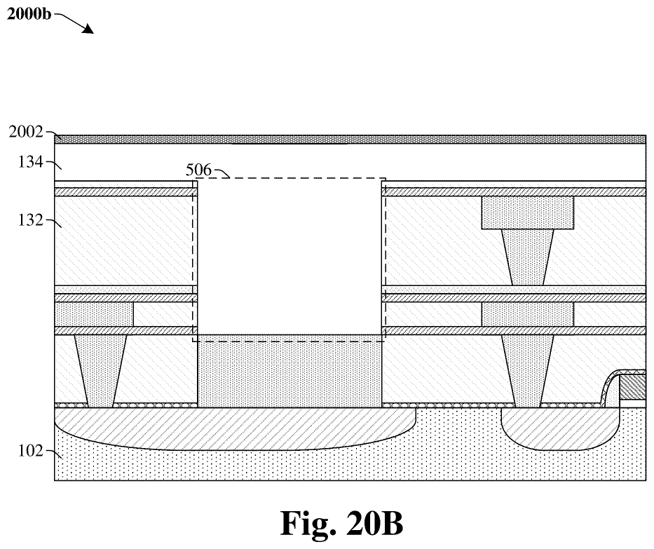

FIGS. 20A-31B illustrate a series of cross-sectional views 2000a-3100b of some embodiments of a method of forming the capacitor of FIGS. 1C and 1D extending from the first lower contact layer to the first upper contact layer between the first bonding layer and the interconnect structure. Although FIGS. 20A-31B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional views 2000a, 2000b of FIGS. 20A and 20B, the low-k layer 134 and an third etch stop layer 2002 are formed over the first substrate 102. The low-k layer 134 fills a first opening 506 (shown in phantom) and extends over upper surfaces of the plurality of ILD layers 132. In some embodiments, the low-k layer 134 is or comprises a low-k insulative material, such as porous silicon dioxide (SiO₂), organosilicate glass (OSG), or the like. In some embodiments, the low-k layer 134 is formed using one or more of a physical vapor deposition (PVD), atomic layer deposition (ALD), chemical vapor deposition (CVD), or the like. In some embodiments, after the low-k layer 134 is formed, a planarization process (e.g., a CMP process) is used to remove portions of the low-k layer 134, resulting in the low-k layer 134 having a substantially flat upper surface. The third etch stop layer 2002 is then formed over the substantially flat upper surface of the low-k layer 134. In some embodiments, the third etch stop layer 2002 is or comprises silicon nitride, silicon oxynitride, or the like.

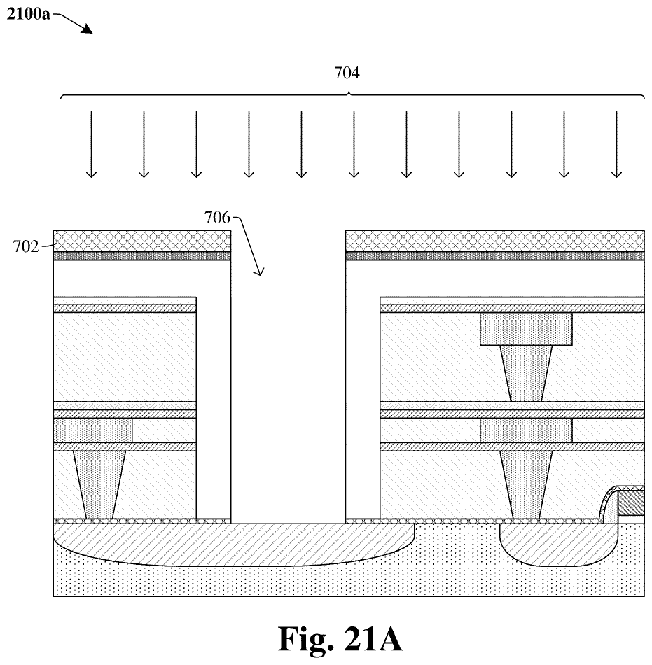

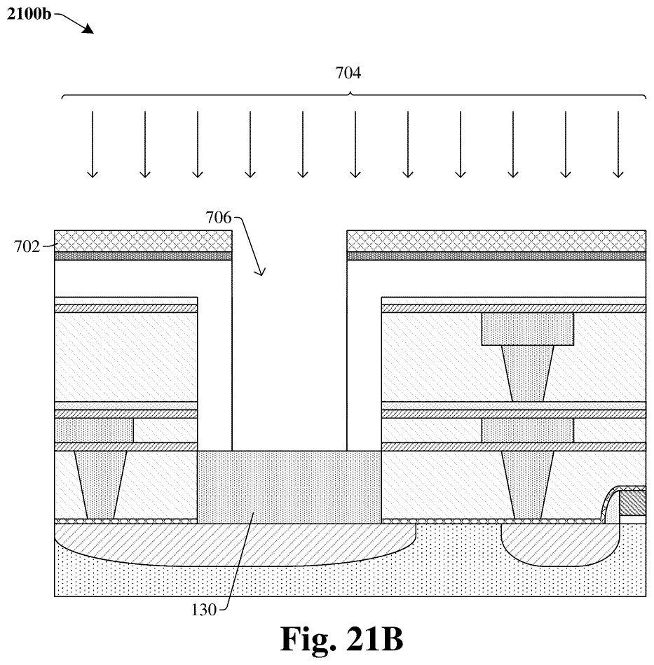

As shown in the cross-sectional views 2100a, 2100b of FIGS. 21A and 21B, the second masking layer 702 is formed over the third etch stop layer 2002. In some embodiments, the second masking layer 702 is or comprises a photoresist and is patterned using photolithography. The second masking layer 702 is patterned to have an opening corresponding to the extension of the capacitor (see 104 of FIG. 1C) through the low-k layer 134.

As shown in FIG. 21A, after the second masking layer 702 is formed, a second etching process 704 is performed, etching through the third etch stop layer 2002, the low-k layer 134 and the CESL 408. As shown in FIG. 21B, the second etching process 704 etches through the third etch stop layer 2002 and the low-k layer 134 to the first lower contact 130. In some embodiments, the second etching process 704 is or comprises a dry etch or the like. The second etching process 704 results in a second opening 706 extending through the low-k layer 134. The second opening 706 corresponds to the opening in the second masking layer 702. The second masking layer 702 is subsequently removed.

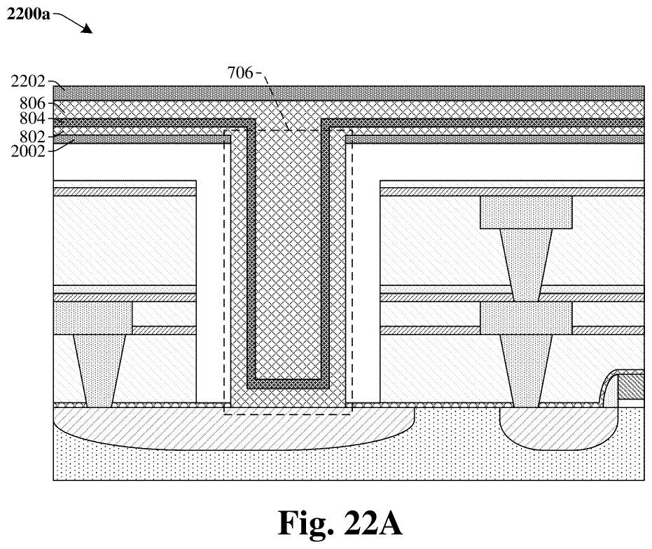

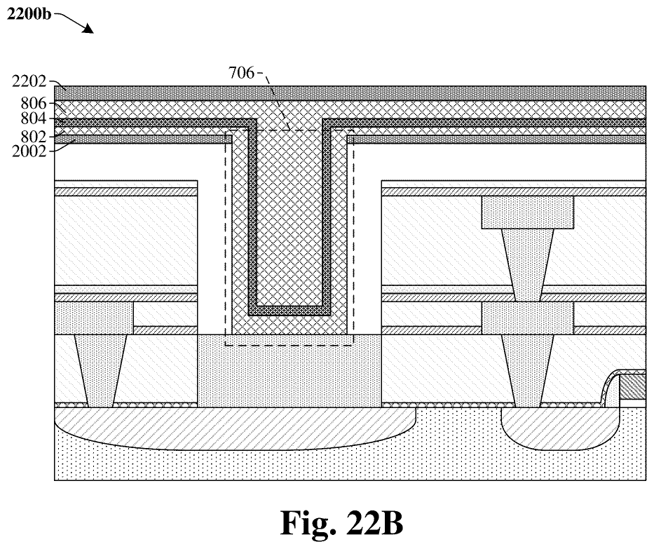

As shown in the cross-sectional views 2200a, 2200b of FIGS. 22A and 22B, a first conformal metal layer 802, a first conformal high-k insulative layer 804, and a second conformal metal layer 806 are formed over the third etch stop layer 2002. The first conformal metal layer 802, the first conformal high-k insulative layer 804, and the second conformal metal layer 806 combined fill the second opening 706 and extend over the upper surface of the third etch stop layer 2002. In some embodiments, the first conformal metal layer 802 and the second conformal metal layer 806 are or comprise a conductive metal, such as titanium (Ti), titanium nitride (TiN), tantalum (Ta), tantalum nitride (TaN), copper (Cu), nickel (Ni), aluminum (Al), tungsten (W), a metal alloy, a combination of the foregoing, or the like. In some embodiments, the first conformal high-k insulative layer 804 is or comprises a high-k insulative material, such as hafnium oxide (HfO₂), hafnium silicate (HfSiO₄), zirconium dioxide (ZrO₂), zirconium silicate (ZrSiO₄), Aluminum oxide (Al₂O₃) or the like. In some embodiments, the first conformal metal layer 802, the first conformal high-k insulative layer 804, and the second conformal metal layer 806 are formed using one or more of PVD, ALD, CVD, or the like.

After the first conformal metal layer 802, the first conformal high-k insulative layer 804, and the second conformal metal layer 806 are formed, a fourth etch stop layer 2202 is formed over the second conformal metal layer 806. In some embodiments, the fourth etch stop layer 2202 is a same material as the third etch stop layer 2002 and is formed using one of PVD, ALD, CVD, or the like.

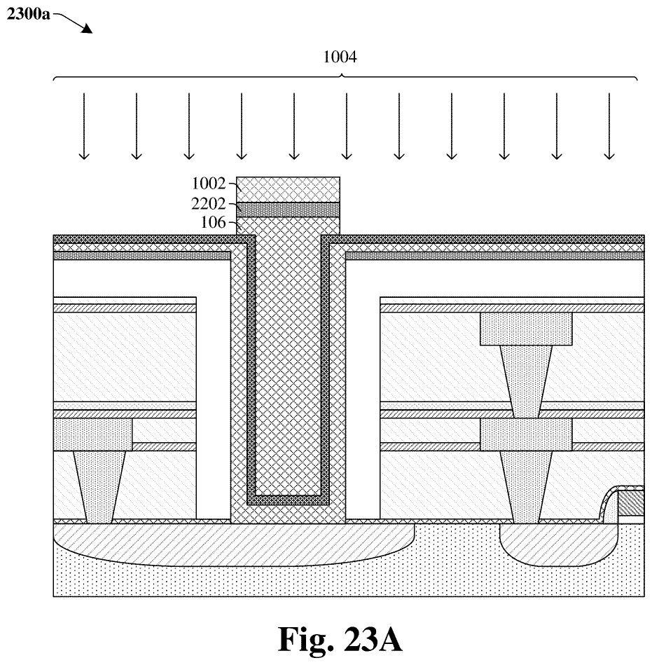

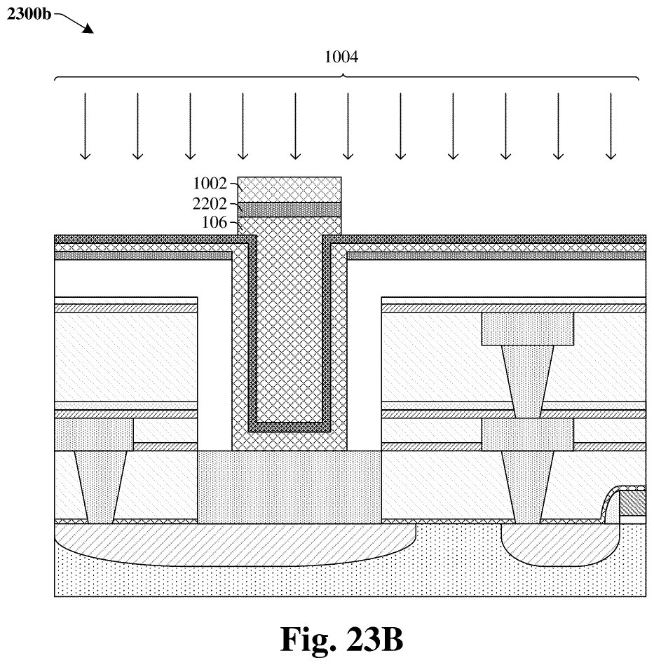

As shown in the cross-sectional views 2300a, 2300b of FIGS. 23A and 23B, in some embodiments, a third masking layer 1002 is formed over the fourth etch stop layer 2202. The third masking layer 1002 is patterned using a capacitor top metal (CTM) mask lithography process and has a pattern corresponding to the lateral dimension of the top electrode 106. Further, a third etch 1004 is performed on the fourth etch stop layer 2202, removing portions of the second conformal metal layer (see 806 of FIG. 8) and the fourth etch stop layer 2202. After the third etch 1004, the top electrode 106 and a portion of the fourth etch stop layer 2202 remain on the first substrate 102. In embodiments including the third masking layer 1002, the third masking layer 1002 is subsequently removed.

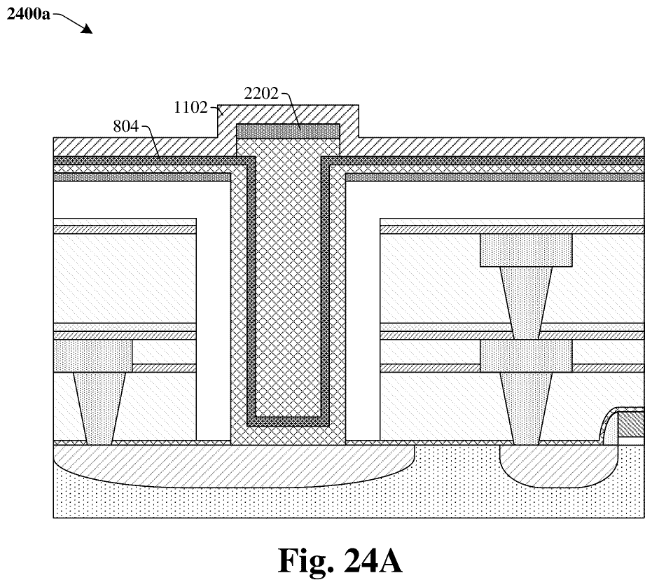

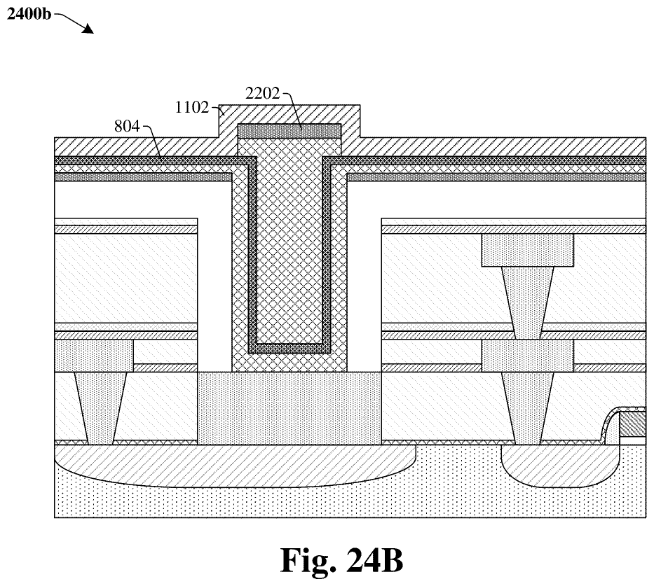

As shown in the cross-sectional views 2400a, 2400b of FIGS. 24A and 24B, the second conformal cap oxide layer 1102 is formed over the fourth etch stop layer 2202 and exposed surfaces of the first conformal high-k insulative layer 804. In some embodiments, the second conformal cap oxide layer 1102 comprises a same material as the cap oxide layer 136. In some embodiments, the second conformal cap oxide layer 1102 is formed using one or more of PVD, ALD, CVD, or the like.

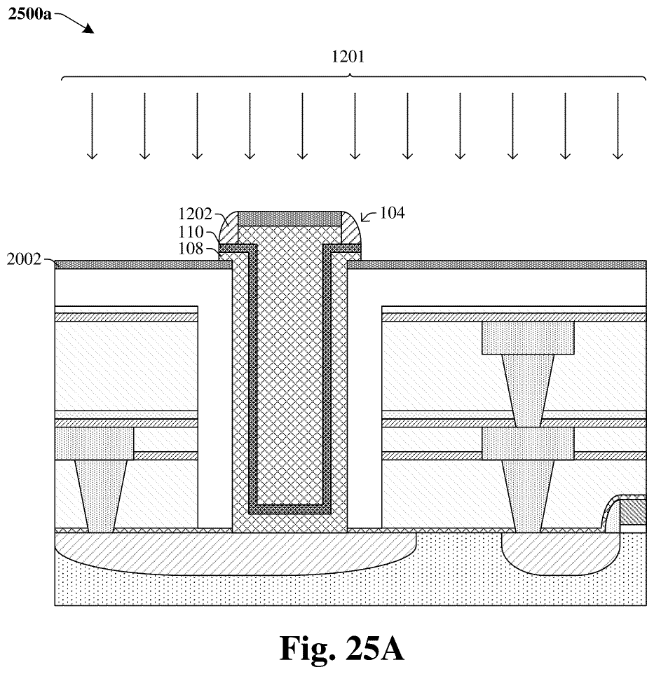

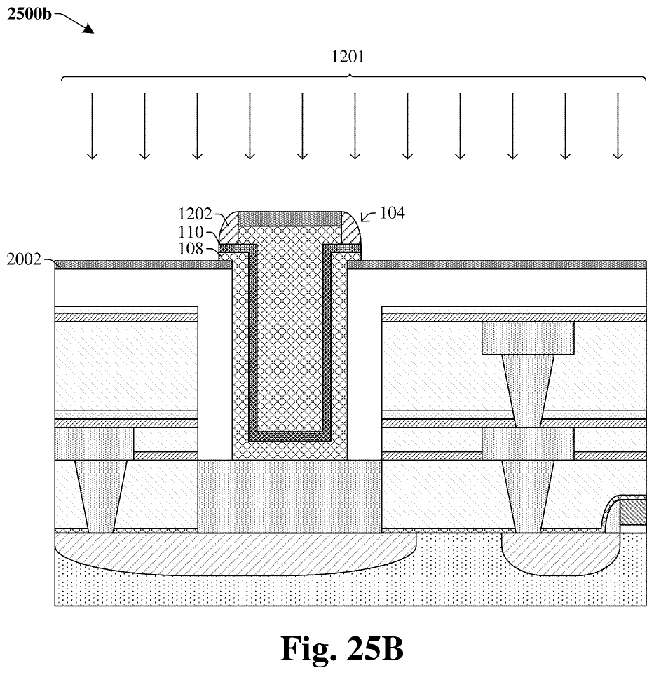

As shown in the cross-sectional views 2500a, 2500b of FIGS. 25A and 25B, a blanket etch 1201 is performed over the first substrate 102. The blanket etch 1201 removes portions of the fourth etch stop layer 2202, the first conformal high-k insulative layer (see 804 of FIG. 8), and the first conformal metal layer (see 802 of FIG. 8). After the blanket etch 1201, the bottom electrode 108, the insulative layer 110, and the oxide spacer 1202 remain on the first substrate 102, and the third etch stop layer 2002 is exposed. The capacitor 104 remains on the first substrate 102.

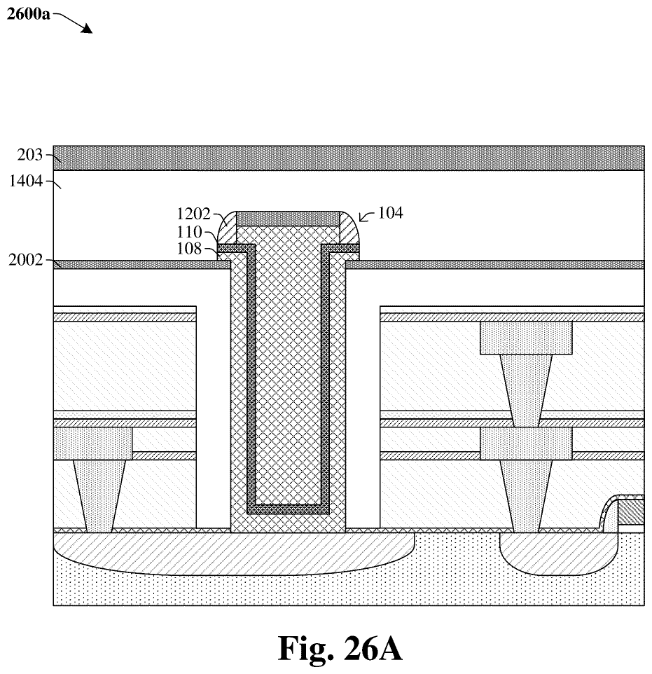

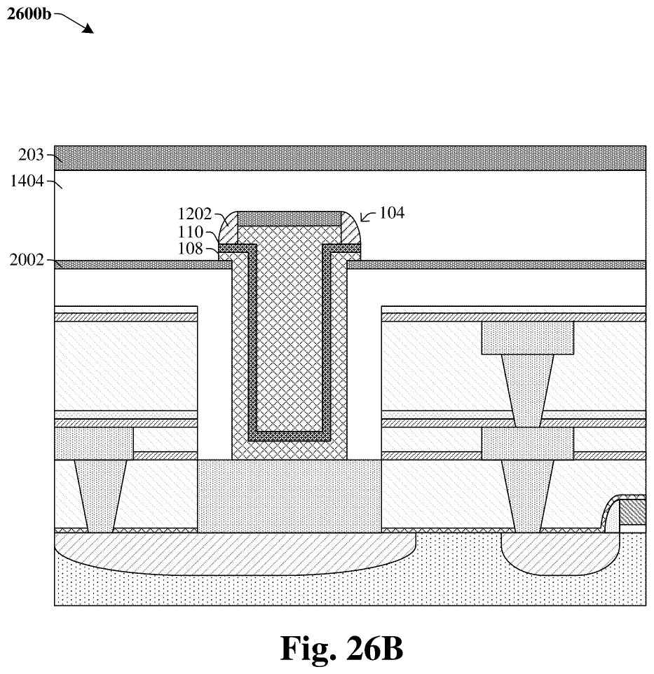

As shown in the cross-sectional views 2600a, 2600b of FIGS. 26A and 26B, an oxide fill layer 1404 and a bonding interface layer 203 are deposited over the third etch stop layer 2002. In some embodiments, the oxide fill layer 1404 is or comprises silicon dioxide (SiO₂), a low-k oxide material, or the like. In some embodiments, the bonding interface layer 203 is or comprises an insulative material such as silicon oxynitride (SiON), or the like. In some embodiments, the oxide fill layer 1404 and the bonding interface layer 203 are formed using one or more of PVD, ALD, CVD, or the like.

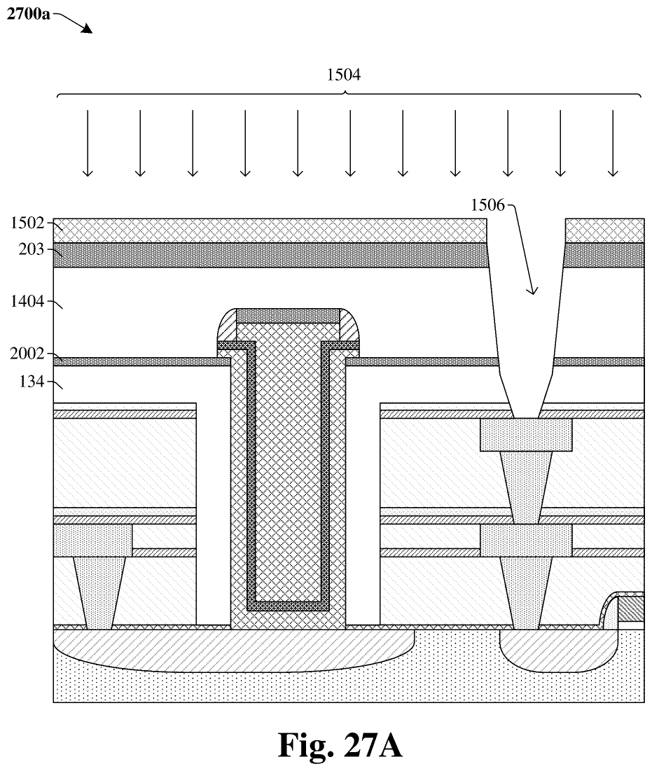

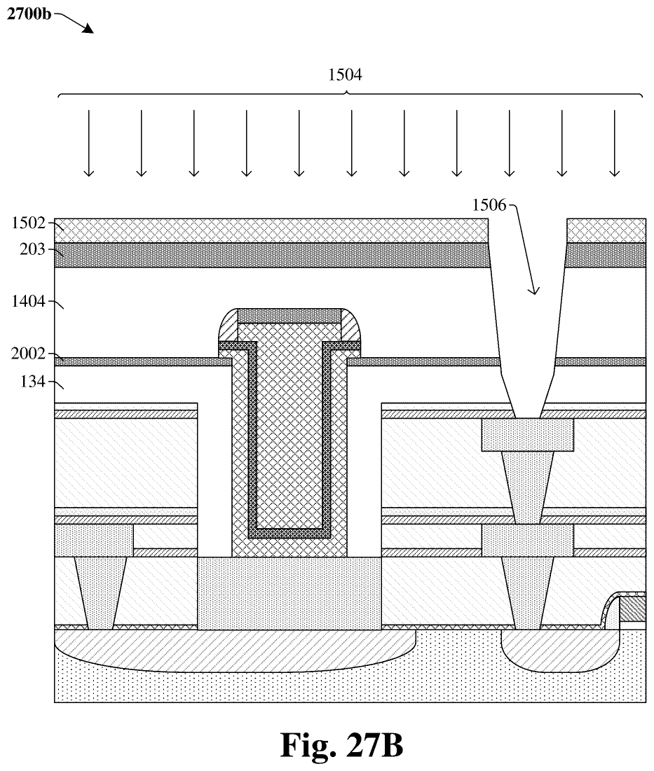

As shown in the cross-sectional views 2700a, 2700b of FIGS. 27A and 27B, a fourth masking layer 1502 is formed over the bonding interface layer 203. In some embodiments, the fourth masking layer 1502 is or comprises a photoresist and is patterned using photolithography. The fourth masking layer 1502 is patterned to have openings corresponding to contacts of the first upper contact layer (see 114 of FIG. 1C).

After the fourth masking layer 1502 is formed, a fourth etching process 1504 is performed, etching through the bonding interface layer 203, the oxide fill layer 1404, the third etch stop layer 2002, and the low-k layer 134. In some embodiments, the fourth etching process 1504 is or comprises a dry etch or the like. The fourth etching process 1504 results in third openings 1506. The third openings 1506 correspond to the openings in the fourth masking layer 1502 and the positions of the contacts of the first upper contact layer (see 114 of FIG. 1C). The fourth masking layer 1502 is subsequently removed.

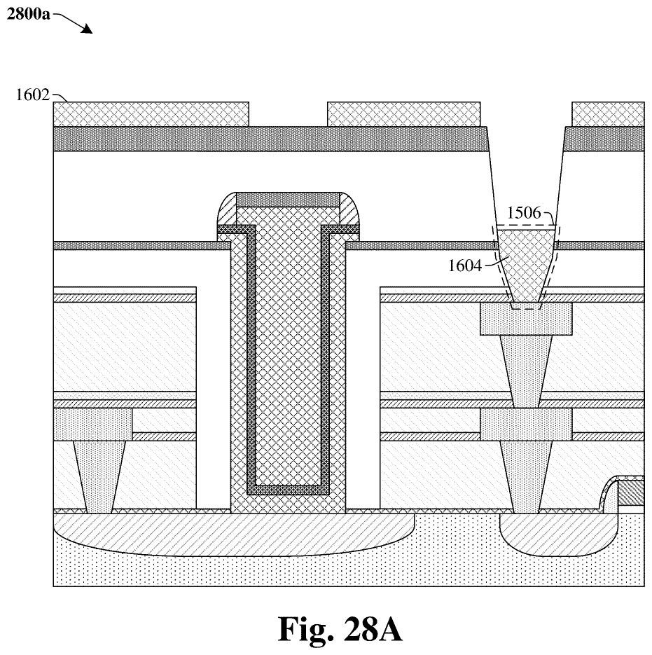

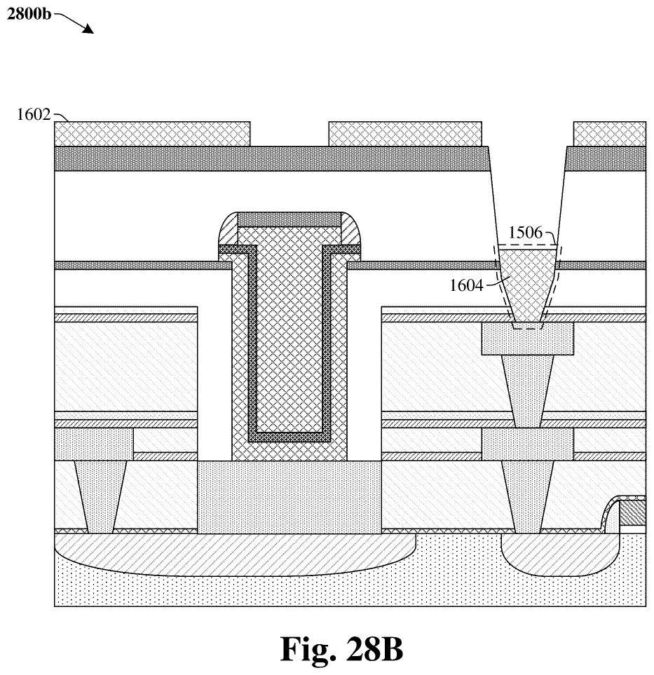

As shown in the cross-sectional views 2800a, 2800b of FIGS. 28A and 28B, a fifth masking layer 1602 is formed over the bonding interface layer 203 and in the third openings 1506. In some embodiments, the fifth masking layer 1602 is or comprises a photoresist and is patterned using photolithography. The fifth masking layer 1602 is patterned to have openings corresponding to bond structures of the first bonding layer (see 116 of FIG. 1A). In some embodiments, portions of the fifth masking layer 1602 form insulative plugs 1604 that reduce the amount of material that is removed in lower portions of the third openings 1506 in the subsequent etching process.

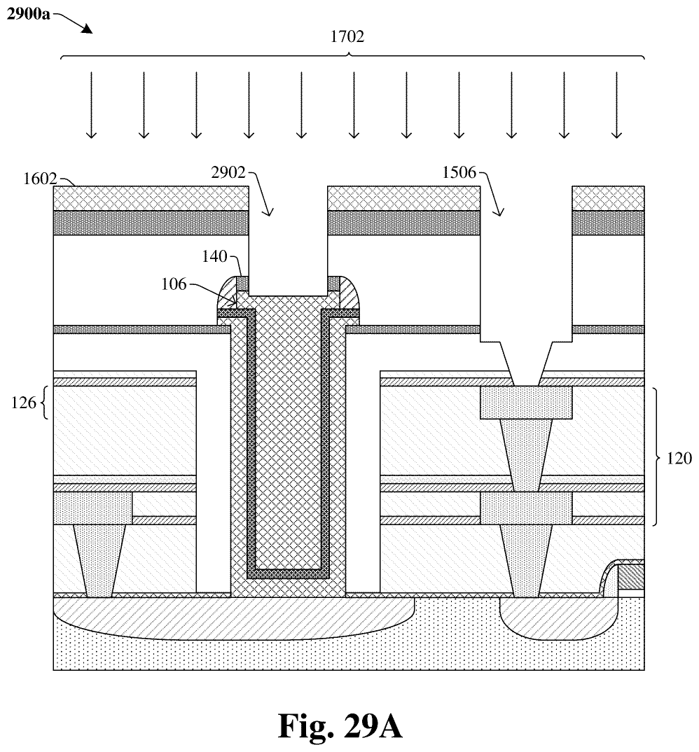

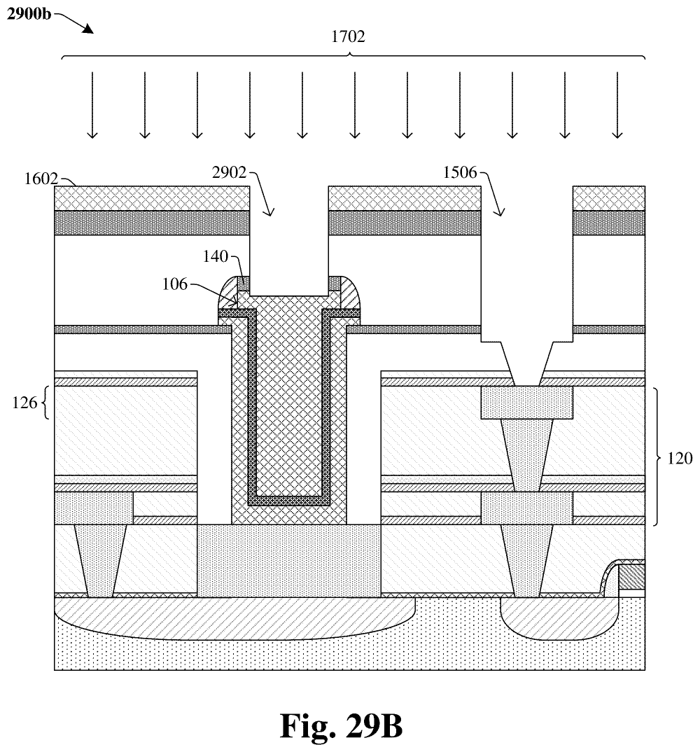

As shown in the cross-sectional views 2900a, 2900b of FIGS. 29A and 29B, after the fifth masking layer 1602 is formed, a fifth etching process 1702 is performed, the fifth etching process 1702 expands the third openings 1506 and creates fourth openings 2902, removing portions of the bonding interface layer 203 and the insulative plugs 1604. In some embodiments, the fifth etching process 1702 is or comprises a dry etch or the like. After the fifth etching process, the fourth opening 2902 corresponding to the position of the first bond structure (see 142 of FIG. 1C) extends to the top electrode 106 through the silicon nitride (Si₃N₄) layer 140. The third openings 1506 corresponding to the position of contacts in the first upper contact layer (see 114 of FIG. 1A) extend to the uppermost wire level 126 of the first interconnect structure 120. Further, upper portions of the third openings corresponding to the bond structures of the first bonding layer (see 116 of FIG. 1C) are etched. The fifth masking layer 1602 is subsequently removed.

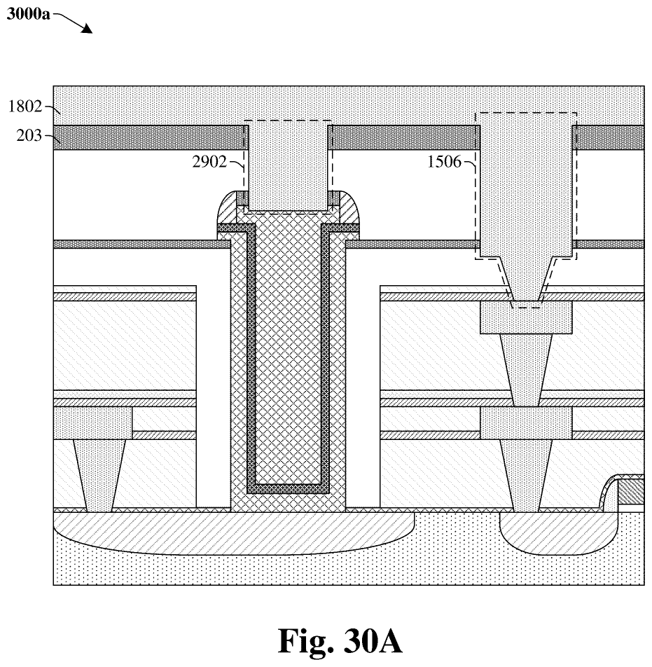

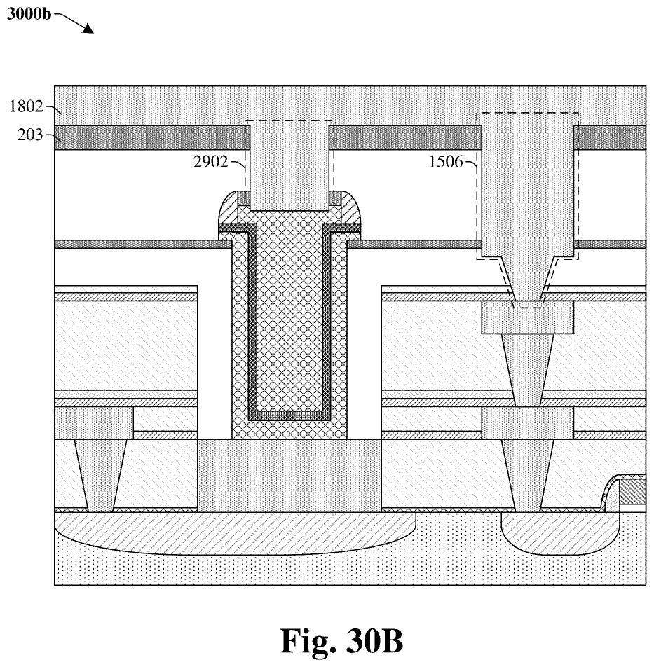

As shown in the cross-sectional views 3000a, 3000b of FIGS. 30A and 30B, a third conformal metal layer 1802 is formed over the bonding interface layer 203. The third conformal metal layer 1802 is or comprises a conductive material, such as copper, nickel, aluminum, tungsten, titanium, titanium nitride, a metal alloy, a combination of the foregoing, or the like. The third conformal metal layer 1802 extends into the third openings 1506 and fourth openings 2902 and over the upper surface of the bonding interface layer 203. In some embodiments, the third conformal metal layer 1802 is formed using one or more of PVD, ALD, CVD, or the like.

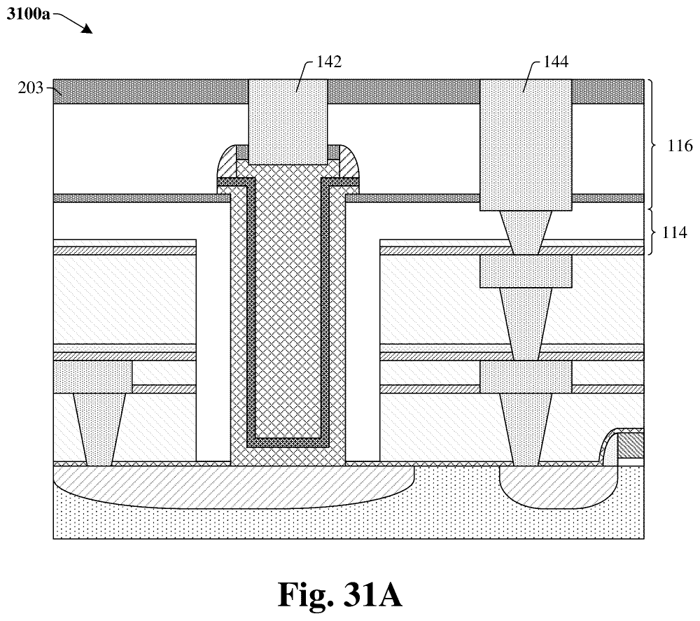

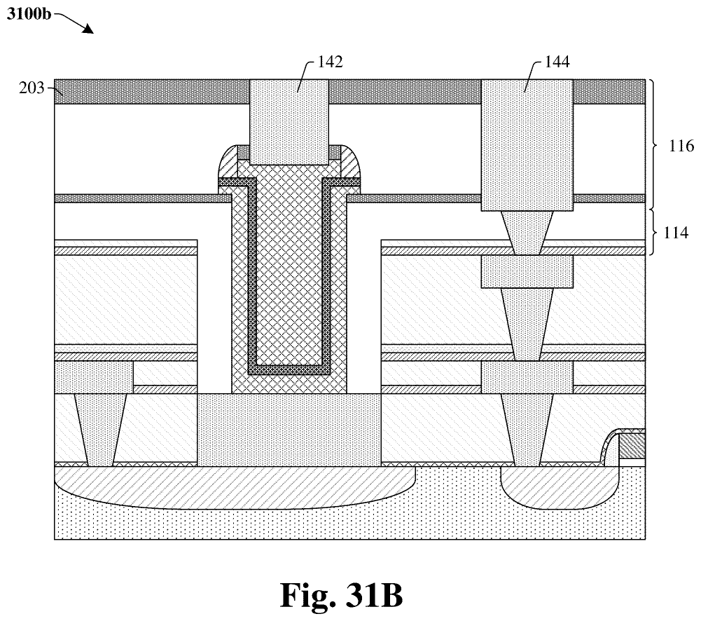

As shown in the cross-sectional views 3100a, 3100b of FIGS. 31A and 31B, a planarization process (e.g., a CMP process) is performed. The planarization process removes portions of the third conformal metal layer (see 1802 of FIG. 18) above the bonding interface layer 203. After the planarization process, the bond structures (e.g., the first bond structure 142 and the second bond structure 144) of the first bonding layer 116 and the contacts of the first upper contact layer 114 remain on first substrate 102.

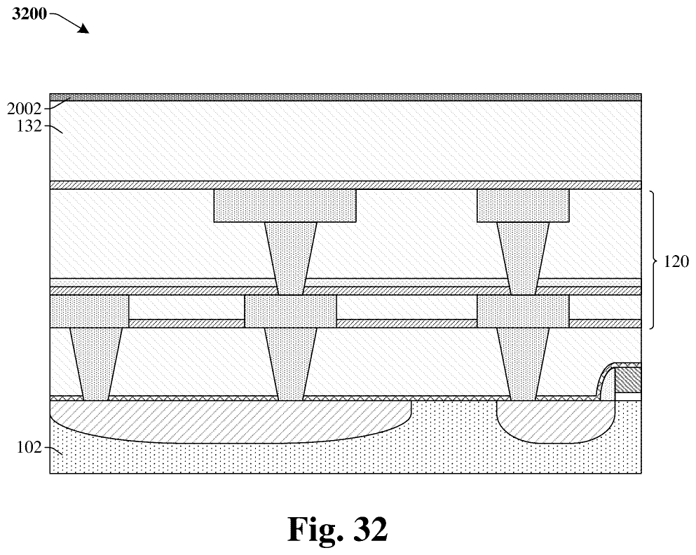

FIGS. 32-44 illustrate a series of cross-sectional views 3200-4400 of some embodiments of a method of forming the capacitor of FIG. 1E extending from the first lower contact layer to the first upper contact layer between the first bonding layer and the interconnect structure. Although FIGS. 32-44 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 3200 of FIG. 32, in some embodiments, the third etch stop layer 2002 is formed on the ILD layers 132. As the capacitor (see 104 of FIG. 1E) to be formed hereafter is formed above the interconnect structure 120, the etching of the ILD layers 132 the deposition of the low-k layer (see 134 of FIG. 1A) are omitted. The third etch stop layer 2002 is formed over the substantially flat upper surface of the ILD layers 132. In some embodiments, the third etch stop layer 2002 is or comprises silicon nitride, silicon oxynitride, or the like. In some embodiments, the third etch stop layer 2002 is formed using a deposition process, such as PVD, ALD, CVD, or the like.

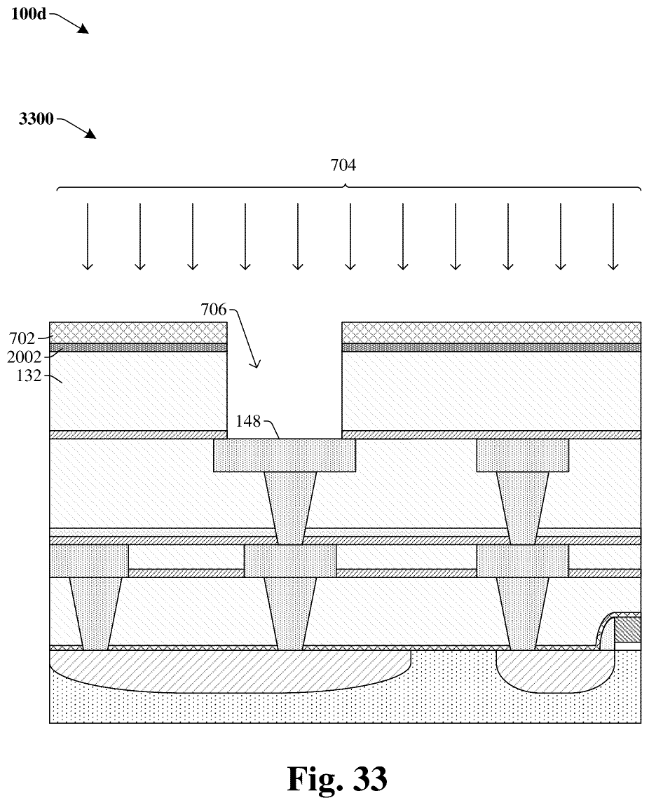

As shown in the cross-sectional view 3300 of FIG. 33, a second masking layer 702 is formed over the third etch stop layer 2002 and the plurality of ILD layers 132. In some embodiments, the second masking layer 702 is or comprises a photoresist and is patterned using photolithography. The second masking layer 702 is patterned to have an opening corresponding to the extension of the capacitor (see 104 of FIG. 1A) into the plurality of ILD layers 132.

After the second masking layer 702 is formed, a second etching process 704 is performed, etching through the plurality of ILD layers 132 to the wire 148. In some embodiments, the second etching process 704 is or comprises a dry etch or the like. The second etching process 704 results in a second opening 706 extending through the plurality of ILD layers 132 to the wire 148. The second opening 706 corresponds to the opening in the second masking layer 702. The second masking layer 702 is subsequently removed.

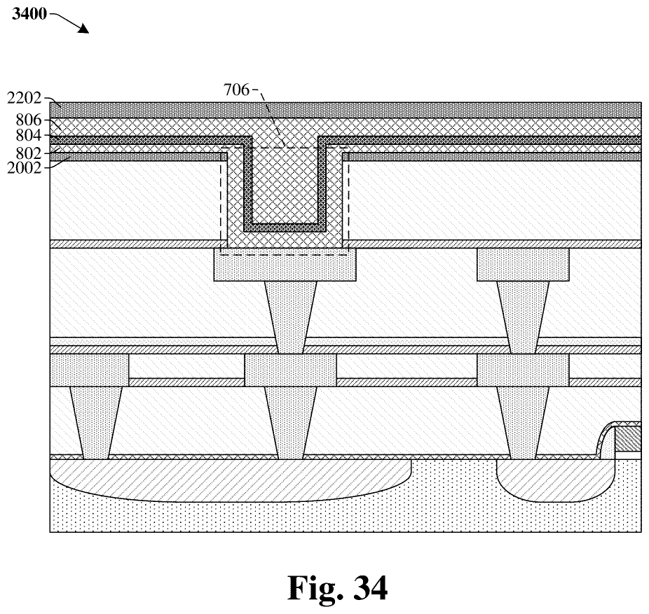

As shown in the cross-sectional view 3400 of FIG. 34, a first conformal metal layer 802, a first conformal high-k insulative layer 804, and a second conformal metal layer 806 are formed over the third etch stop layer 2002. The first conformal metal layer 802, the first conformal high-k insulative layer 804, and the second conformal metal layer 806 combined fill the second opening 706 and extend over the upper surface of the third etch stop layer 2002. In some embodiments, the first conformal metal layer 802 and the second conformal metal layer 806 are or comprise a conductive metal, such as titanium (Ti), titanium nitride (TiN), tantalum (Ta), tantalum nitride (TaN), copper (Cu), nickel (Ni), aluminum (Al), tungsten (W), a metal alloy, a combination of the foregoing, or the like. In some embodiments, the first conformal high-k insulative layer 804 is or comprises a high-k insulative material, such as hafnium oxide (HfO₂), hafnium silicate (HfSiO₄), zirconium dioxide (ZrO₂), zirconium silicate (ZrSiO₄), Aluminum oxide (Al₂O₃) or the like. In some embodiments, the first conformal metal layer 802, the first conformal high-k insulative layer 804, and the second conformal metal layer 806 are formed using one or more of PVD, ALD, CVD, or the like.

After the first conformal metal layer 802, the first conformal high-k insulative layer 804, and the second conformal metal layer 806 are formed, a fourth etch stop layer 2202 is formed over the second conformal metal layer 806. In some embodiments, the fourth etch stop layer 2202 is a same material as the third etch stop layer 2002 and is formed using one of PVD, ALD, CVD, or the like.

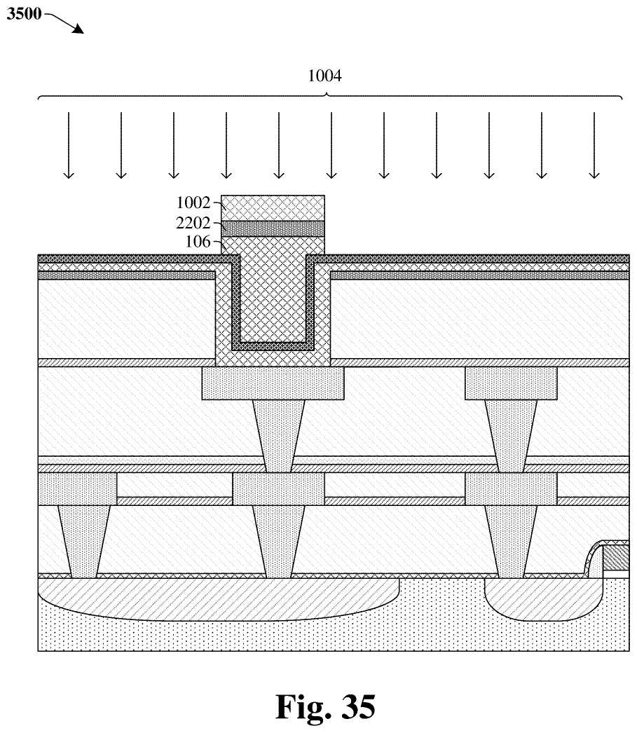

As shown in the cross-sectional view 3500 of FIGS. 35, in some embodiments, a third masking layer 1002 is formed over the fourth etch stop layer 2202. The third masking layer 1002 is patterned using a capacitor top metal (CTM) mask lithography process and has a pattern corresponding to the lateral dimension of the top electrode 106. Further, a third etch 1004 is performed on the fourth etch stop layer 2202, removing portions of the second conformal metal layer (see 806 of FIG. 8) and the fourth etch stop layer 2202. After the third etch 1004, the top electrode 106 and a portion of the fourth etch stop layer 2202 remain on the first substrate 102. In embodiments including the third masking layer 1002, the third masking layer 1002 is subsequently removed.

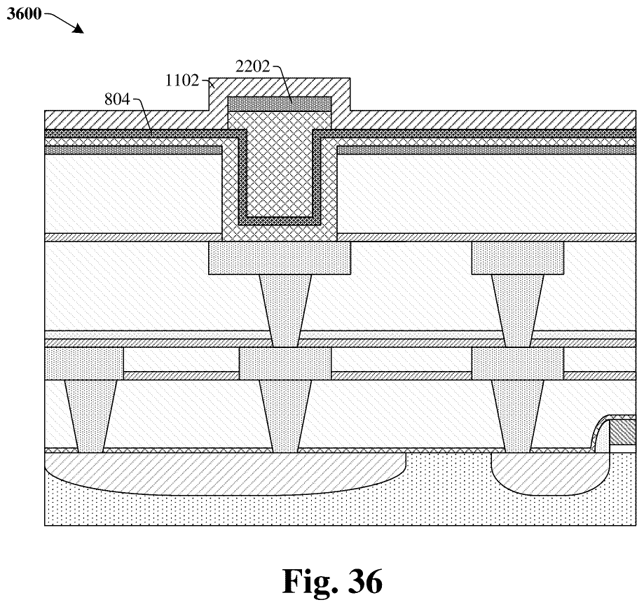

As shown in the cross-sectional view 3600 of FIG. 36, the second conformal cap oxide layer 1102 is formed over the fourth etch stop layer 2202 and exposed surfaces of the first conformal high-k insulative layer 804. In some embodiments, the second conformal cap oxide layer 1102 comprises a same material as the cap oxide layer (see 136 of FIG. 1B). In some embodiments, the second conformal cap oxide layer 1102 is formed using one or more of PVD, ALD, CVD, or the like.

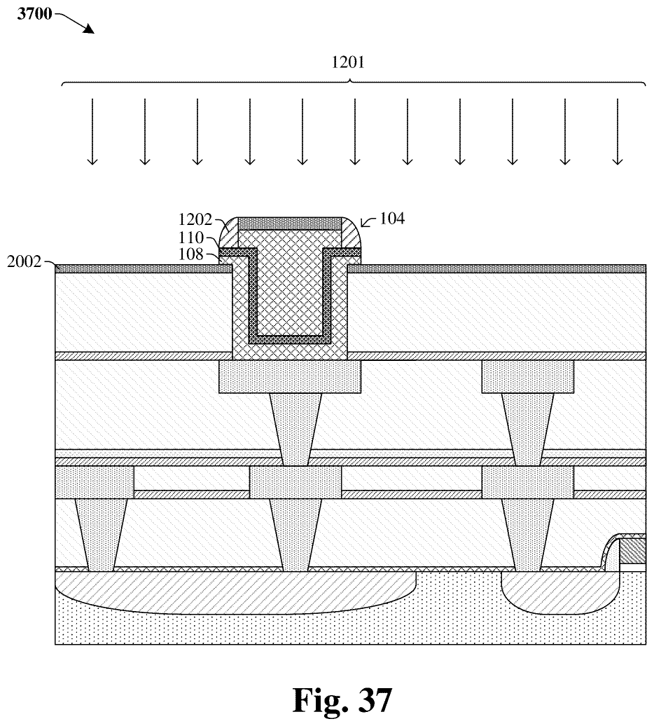

As shown in the cross-sectional view 3700 of FIG. 37, a blanket etch 1201 is performed over the first substrate 102. The blanket etch 1201 removes portions of the fourth etch stop layer 2202, the first conformal high-k insulative layer (see 804 of FIG. 8), and the first conformal metal layer (see 802 of FIG. 8). After the blanket etch 1201, the bottom electrode 108, the insulative layer 110, and the oxide spacer 1202 remain on the first substrate 102, and the third etch stop layer 2002 is exposed. The capacitor 104 remains on the first substrate 102.

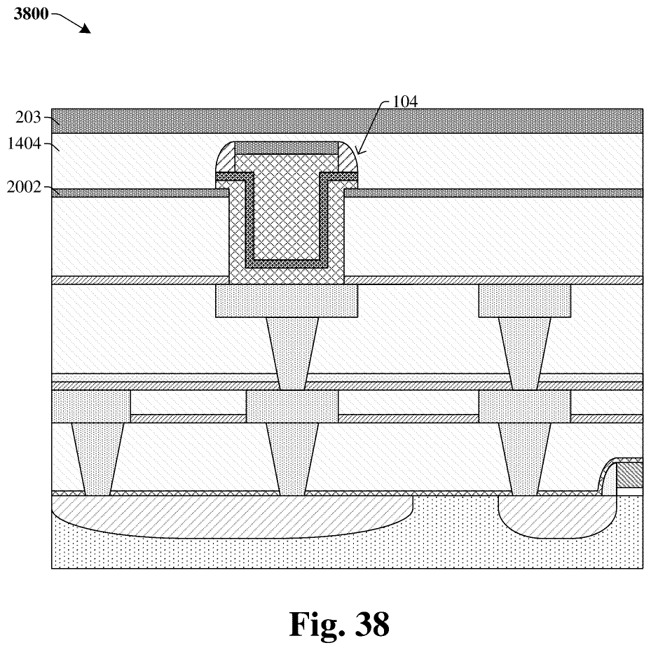

As shown in the cross-sectional view 3800 of FIG. 38, an oxide fill layer 1404 and a bonding interface layer 203 are deposited over the third etch stop layer 2002. In some embodiments, the oxide fill layer 1404 is or comprises silicon dioxide (SiO₂), a low-k oxide material, or the like. In some embodiments, the bonding interface layer 203 is or comprises an insulative material such as silicon oxynitride (SiON), or the like. In some embodiments, the oxide fill layer 1404 and the bonding interface layer 203 are formed using one or more of PVD, ALD, CVD, or the like.

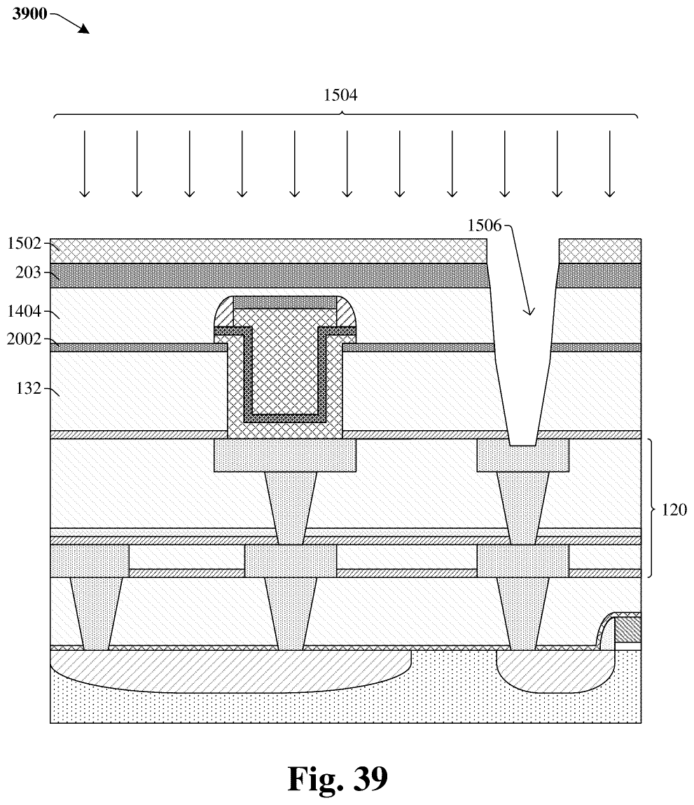

As shown in the cross-sectional view 3900 of FIG. 39, a fourth masking layer 1502 is formed over the bonding interface layer 203. In some embodiments, the fourth masking layer 1502 is or comprises a photoresist and is patterned using photolithography. The fourth masking layer 1502 is patterned to have openings corresponding to contacts of the first upper contact layer (see 114 of FIG. 1C).

After the fourth masking layer 1502 is formed, a fourth etching process 1504 is performed, etching through the bonding interface layer 203, the oxide fill layer 1404, the third etch stop layer 2002, and the ILD layers 132 above the interconnect structure 120. In some embodiments, the fourth etching process 1504 is or comprises a dry etch or the like. The fourth etching process 1504 results in third openings 1506. The third openings 1506 correspond to the openings in the fourth masking layer 1502 and the positions of the contacts of the first upper contact layer (see 114 of FIG. 1C). The fourth masking layer 1502 is subsequently removed.

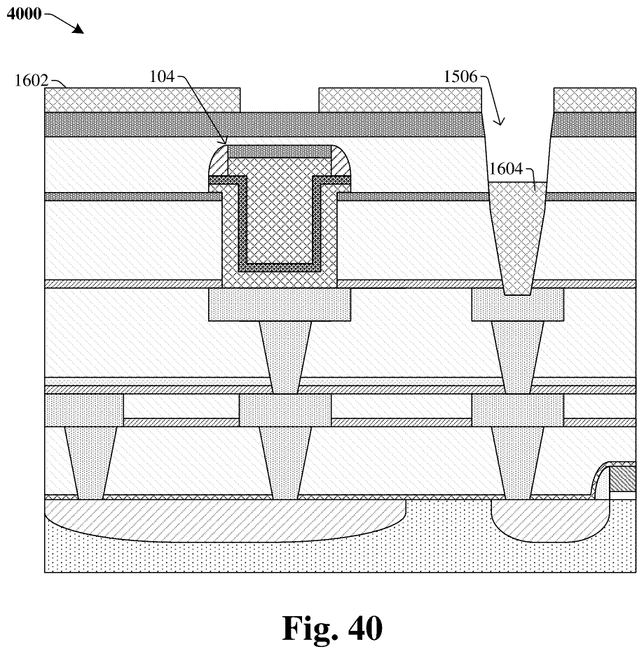

As shown in the cross-sectional view 4000 of FIG. 40, a fifth masking layer 1602 is formed over the bonding interface layer 203 and in the third openings 1506. In some embodiments, the fifth masking layer 1602 is or comprises a photoresist and is patterned using photolithography. The fifth masking layer 1602 is patterned to have openings corresponding to bond structures of the first bonding layer (see 116 of FIG. 1A). In some embodiments, portions of the fifth masking layer 1602 form insulative plugs 1604 that reduce the amount of material that is removed in lower portions of the third openings 1506 in the subsequent etching process.

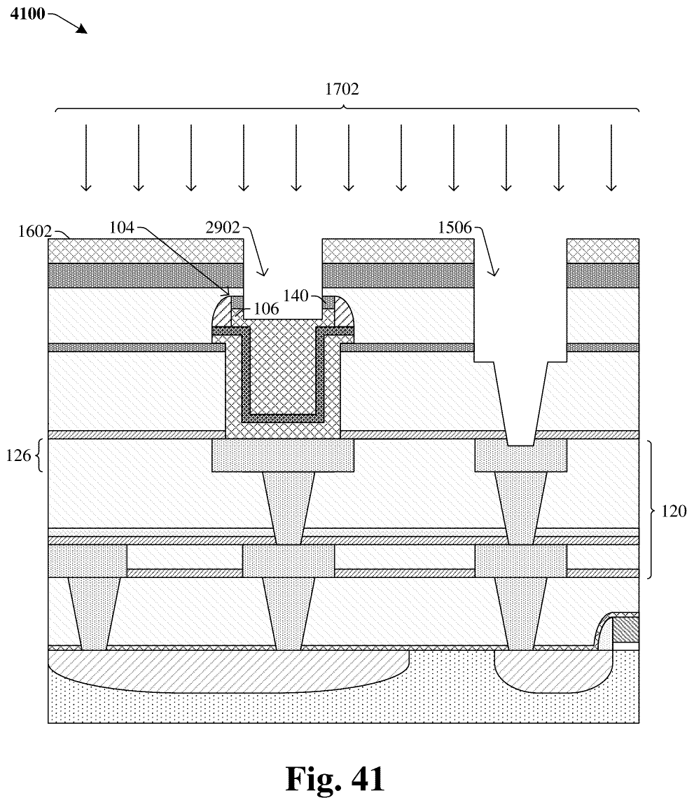

As shown in the cross-sectional view 4100 of FIG. 41, after the fifth masking layer 1602 is formed, a fifth etching process 1702 is performed, the fifth etching process 1702 expands the third openings 1506 and creates fourth openings 2902, removing portions of the bonding interface layer 203 and the insulative plugs (see 1604 of FIG. 40). In some embodiments, the fifth etching process 1702 is or comprises a dry etch or the like. After the fifth etching process, the fourth opening 2902 corresponding to the position of the first bond structure (see 142 of FIG. 1C) extends to the top electrode 106 through the silicon nitride (Si₃N₄) layer 140. The third openings 1506 corresponding to the position of contacts in the first upper contact layer (see 114 of FIG. 1A) extend to the uppermost wire level 126 of the first interconnect structure 120. Further, upper portions of the third openings corresponding to the bond structures of the first bonding layer (see 116 of FIG. 1C) are etched. The fifth masking layer 1602 is subsequently removed.

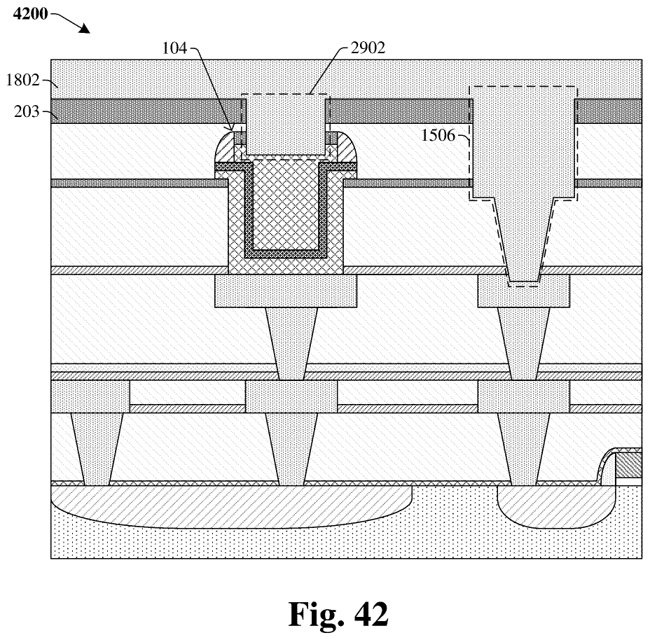

As shown in the cross-sectional view 4200 of FIG. 42, a third conformal metal layer 1802 is formed over the bonding interface layer 203. The third conformal metal layer 1802 is or comprises a conductive material, such as copper, nickel, aluminum, tungsten, titanium, titanium nitride, a metal alloy, a combination of the foregoing, or the like. The third conformal metal layer 1802 extends into the third openings 1506 and fourth openings 2902 and over the upper surface of the bonding interface layer 203. In some embodiments, the third conformal metal layer 1802 is formed using one or more of PVD, ALD, CVD, or the like.

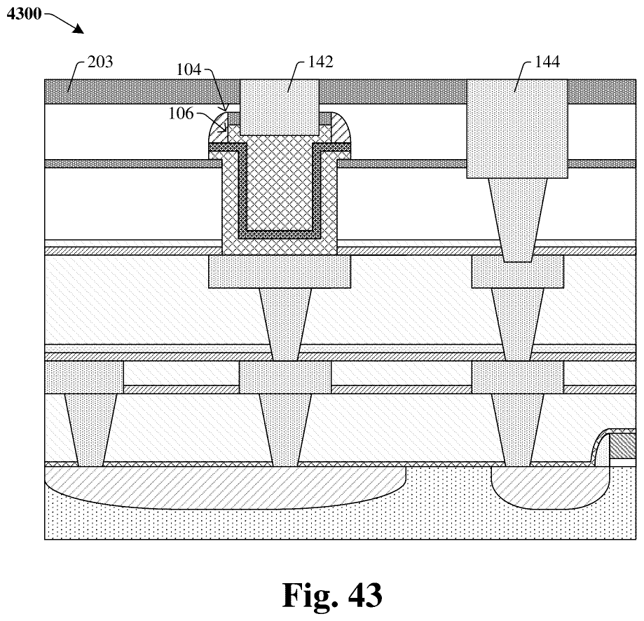

As shown in the cross-sectional view 4300 of FIG. 43, a planarization process (e.g., a CMP process) is performed. The planarization process removes portions of the third conformal metal layer (see 1802 of FIG. 18) above the bonding interface layer 203. After the planarization process, the bond structures (e.g., the first bond structure 142 and the second bond structure 144) of the first bonding layer 116 and the contacts of the first upper contact layer 114 remain on first substrate 102.

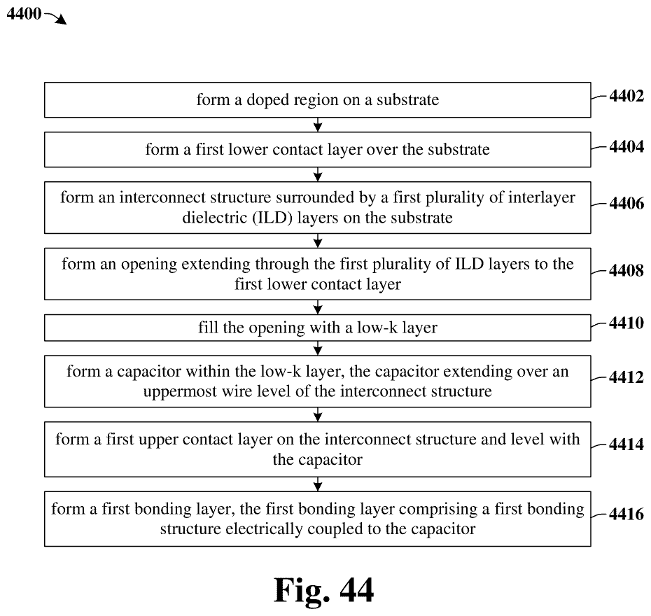

FIG. 44 illustrates a flowchart 4400 of some embodiments of a method of forming a capacitor extending between a first lower contact layer at a substrate and a first upper contact layer at a first bonding layer. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 4402, a doped region is formed on a substrate. An example of a drawing illustrating this step can be found, for example, in FIGS. 4A-4B.

At 4404, a first lower contact layer is formed over the substrate. An example of a drawing illustrating this step can be found, for example, in FIGS. 4A-4B.

At 4406, an interconnect structure surrounded by a first plurality of interlayer dielectric (ILD) layers is formed on the substrate. An example of a drawing illustrating this step can be found, for example, in FIGS. 4A-4B.

At 4408, an opening is formed, the opening extending through the first plurality of ILD layers to the first lower contact layer. An example of a drawing illustrating this step can be found, for example, in FIGS. 5A-5B.

At 4410, the opening is filled with a low-k layer. An example of a drawing illustrating this step can be found, for example, in FIGS. 6A-6B.

At 4412, a capacitor is formed within the low-k layer, the capacitor extending over an uppermost wire level of the interconnect structure. An example of a drawing illustrating this step can be found, for example, in FIGS. 7A-12B.

At 4414, a first upper contact layer is formed on the interconnect structure and level with the capacitor. An example of a drawing illustrating this step can be found, for example, in FIG. 15A-19B.

At 4416, a first bonding layer is formed, the first bonding layer comprising a first bonding structure electrically coupled to the capacitor. An example of a drawing illustrating this step can be found, for example, in FIGS. 15A-19B.

Some embodiments relate to an integrated device, including: a substrate including a first doped region; an interconnect structure on the substrate and including a plurality of wire levels and via levels; a first lower contact layer extending between the substrate and the interconnect structure; a first bonding layer over the interconnect structure; a first upper contact layer extending between the interconnect structure and the first bonding layer; a capacitor in the interconnect structure, wherein the capacitor extends above an uppermost wire level of the plurality of wire levels and via levels. In some embodiments, the capacitor includes a bottom electrode with a bottommost surface extending through the first lower contact layer to the first doped region. In some embodiments, the integrated device further includes: a bottom electrode of the capacitor; and a first lower contact of the first lower contact layer electrically coupling the bottom electrode to the first doped region. In some embodiments, the capacitor further includes a top electrode with an uppermost surface level with or above a bottom surface of a first bond structure of the first bonding layer. In some embodiments, the integrated device further includes a top electrode of the capacitor; and a first upper contact of the first upper contact layer electrically coupling the top electrode to a first bond structure of the first bonding layer. In some embodiments, the integrated device further includes a low-k layer extending from the first lower contact layer to the first upper contact layer and having outer sidewalls contacting a plurality of interlayer dielectric (ILD) layers. In some embodiments, the plurality of ILD layers surround outer sidewalls of the first lower contact layer and the interconnect structure, and the low-k layer extends to the first lower contact layer through an opening in the plurality of ILD layers.

Other embodiments relate to an integrated device, including: a first substrate; a capacitor over the first substrate and comprising a bottom electrode and a top electrode; a first bonding layer over the capacitor; a second bonding layer bonded to the first bonding layer; a first lower contact layer coupled to the first substrate and level with the bottom electrode; a first upper contact layer coupled to the first bonding layer and level with the top electrode; and a low-k layer surrounding the capacitor and extending from first lower contact layer to the first upper contact layer. In some embodiments, an uppermost surface of the first lower contact layer is level with a lowermost surface of the bottom electrode of the capacitor. In some embodiments, a lowermost surface of the first upper contact layer is level with the lowermost surface of the bottom electrode of the capacitor. In some embodiments, the integrated device further includes: a second substrate over the first substrate, wherein the second bonding layer is on the second substrate; a first interconnect structure extending between the first substrate and the first bonding layer and comprising a first plurality of wire levels and a first plurality of via levels; and a second interconnect structure extending between the second substrate and the second bonding layer and comprising a second plurality of wire levels and a second plurality of via levels; wherein the capacitor extends above an uppermost wire level of the first plurality of wire levels. In some embodiments, the integrated device further comprises a plurality of interlayer dielectric (ILD) layers surrounding the first interconnect structure, wherein the low-k layer spaces the plurality of ILD layers from the capacitor.

Yet other embodiments relate to a method of forming an integrated device, includes: forming a doped region on a substrate, forming an interconnect structure surrounded by a first plurality of interlayer dielectric (ILD) layers on the substrate; forming an opening extending through the first plurality of ILD layers; filling the opening with a low-k layer; forming a capacitor within the low-k layer, the capacitor extending over an uppermost wire level of the interconnect structure; and forming a first bonding layer, the first bonding layer comprising a first bonding structure electrically coupled to the capacitor. In some embodiments, the bond electrode and the shield electrode form a capacitor electrically coupled from the output node to the floating diffusion node. In some embodiments, the method further includes: forming a first lower contact layer on the substrate before forming the interconnect structure, wherein the capacitor extends to the first lower contact layer. In some embodiments, forming the first lower contact layer includes forming a first lower contact electrically coupled to the doped region, wherein the opening is directly over the first lower contact and the capacitor contacts the first lower contact. In some embodiments, the low-k layer extends to a bottom surface of a bottommost ILD layer of the plurality of ILD layers, and the capacitor extends to the substrate. In some embodiments, the method further includes forming an upper contact layer concurrently with forming the first bonding layer, wherein an uppermost surface of a top electrode of the capacitor is level with or above the upper contact layer. In some embodiments, a first upper contact of the upper contact layer electrically couples the top electrode to the first bonding structure. In some embodiments, an uppermost surface of the top electrode is level with the first bonding structure. In some embodiments, the method further includes bonding a second bonding layer on a second substrate to the first bonding structure using metal-to-metal bonding.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate comprising a first doped region;
an interconnect structure on the substrate and comprising a plurality of wire levels and a plurality of via levels;
a first lower contact layer extending between the substrate and the interconnect structure;
a first bonding layer over the interconnect structure;
a first upper contact layer extending between the interconnect structure and the first bonding layer; and
a capacitor in the interconnect structure, wherein the capacitor includes: a bottom electrode having a bottommost surface coupled to the first doped region, a top electrode that extends above an uppermost wire level of the plurality of wire levels, and an insulative layer separating the bottom electrode from the top electrode.

2. The integrated device of claim 1, wherein the bottom electrode includes a base portion having a bottommost surface contacting the first doped region, and a sleeve portion extending upwards from the base portion, and
wherein the top electrode includes a protrusion arranged within the sleeve portion of the bottom electrode, the protrusion having an uppermost portion over an upper surface of the uppermost wire level and a lowermost portion below a bottom surface of a via level immediately below the uppermost wire level.

3. The integrated device of claim 1, further comprising:
a first lower contact of the first lower contact layer electrically coupling the bottom electrode to the first doped region.

4. The integrated device of claim 1, wherein the top electrode has an uppermost surface level with or above a bottom surface of a first bond structure of the first bonding layer.

5. The integrated device of claim 1, further comprising:
a first upper contact of the first upper contact layer electrically coupling the top electrode to a first bond structure of the first bonding layer.

6. The integrated device of claim 1, further comprising a low-k layer extending from the first lower contact layer to the first upper contact layer and having outer sidewalls contacting a plurality of interlayer dielectric (ILD) layers.

7. The integrated device of claim 6, wherein the plurality of ILD layers surround outer sidewalls of the first lower contact layer and the interconnect structure, and the low-k layer extends to the first lower contact layer through an opening in the plurality of ILD layers.

8. An integrated device, comprising:
a first substrate;
a capacitor over the first substrate and comprising a bottom electrode and a top electrode;
a first bonding layer over the capacitor;
a second bonding layer bonded to the first bonding layer;
a first lower contact layer coupled to the first substrate and level with the bottom electrode;
a first upper contact layer coupled to the first bonding layer and level with the top electrode; and
a low-k layer surrounding the capacitor and extending from first lower contact layer to the first upper contact layer.

9. The integrated device of claim 8, wherein an uppermost surface of a first lower contact of the first lower contact layer is level with or above a lowermost surface of the bottom electrode of the capacitor.

10. The integrated device of claim 8, wherein a lowermost surface of the first upper contact layer is level with or beneath the uppermost surface of the top electrode of the capacitor.

11. The integrated device of claim 8, further comprising:
a second substrate over the first substrate, wherein the second bonding layer is on the second substrate;
a first interconnect structure extending between the first substrate and the first bonding layer and comprising a first plurality of wire levels and a first plurality of via levels; and
a second interconnect structure extending between the second substrate and the second bonding layer and comprising a second plurality of wire levels and a second plurality of via levels;
wherein the capacitor extends above an uppermost wire level of the first plurality of wire levels and is coupled to the second interconnect structure through the first and second bonding layers.

12. The integrated device of claim 11, further comprising a plurality of interlayer dielectric (ILD) layers surrounding the first interconnect structure, wherein the low-k layer spaces the plurality of ILD layers from the capacitor.

13. A method of forming an integrated device, comprising:
forming a doped region on a substrate;
forming an interconnect structure surrounded by a first plurality of interlayer dielectric (ILD) layers on the substrate;
forming an opening extending through the first plurality of ILD layers;
filling the opening with a low-k layer;
forming a capacitor within the low-k layer, the capacitor extending over an uppermost wire level of the interconnect structure; and
forming a first bonding layer, the first bonding layer comprising a first bonding structure electrically coupled to the capacitor.

14. The method of claim 13, further comprising:
forming a first lower contact layer on the substrate before forming the interconnect structure, wherein the capacitor extends to the first lower contact layer.

15. The method of claim 14, wherein forming the first lower contact layer comprises forming a first lower contact electrically coupled to the doped region, and wherein the opening is directly over the first lower contact and the capacitor contacts the first lower contact.

16. The method of claim 13, wherein the low-k layer extends to a bottom surface of a bottommost ILD layer of the plurality of ILD layers, and the capacitor extends to the substrate.

17. The method of claim 13, further comprising forming an upper contact layer concurrently with forming the first bonding layer, wherein an uppermost surface of a top electrode of the capacitor is level with or above the upper contact layer.

18. The method of claim 17, wherein a first upper contact of the upper contact layer electrically couples the top electrode to the first bonding structure.

19. The method of claim 17, wherein an uppermost surface of the top electrode is level with the first bonding structure.

20. The method of claim 13, further comprising bonding a second bonding layer on a second substrate to the first bonding structure using metal-to-metal bonding.
